(19) United States
(12) Patent Application Publication
(10) Pub. No.: US 2023/0200080 A1
(43) Pub. Date: Jun. 22, 2023

(54) 3D FERROELECTRIC MEMORY CELL ARCHITECTURES

(71) Applicant: Intel Corporation, Santa Clara, CA (US)

(72) Inventors: Abhishek A. Sharma, Portland, OR (US); Wilfred Gomes, Portland, OR (US); Uygar Avci, Portland, OR (US)

(73) Assignee: Intel Corporation, Santa Clara, CA (US)

(21) Appl. No.: 17/558,419

(22) Filed: Dec. 21, 2021

(51) Int. Cl. H01L 27/11514; G11C 11/22; H01L 27/11504

(52) U.S. Cl. CPC H01L 27/11514; G11C 11/221; H01L 27/11504

(57) ABSTRACT

Three-dimensional ferroelectric memory cell architectures are discussed related to improved memory cell performance and density. Such three-dimensional ferroelectric memory cell architectures include groups of vertically stacked transistors accessed by vertical bit lines and horizontal word lines. Groups of such stacks of transistors are arrayed laterally. Adjacent transistor stacks are separated by isolation material or memory structures inclusive of capacitor structures or plate line structures.

### BACKGROUND

Demand for integrated circuits (ICs) in portable electronic applications has motivated higher levels of semiconductor device performance. For example, devices demand memory solutions that use lower power, perform read and write operations more quickly, and offer improved reliability. Furthermore, ever more compact memory architectures are desirable. It is with respect to these and other considerations that the present improvements have been needed. Such improvements may become critical as increased memory performance is needed to drive higher performance integrated circuit electronic devices.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1A provides an isometric view of an exemplary 3D memory device, FIG. 1B illustrates a view taken along a plane across the transistor and capacitor of each memory cell of the 3D memory device of FIG. 1A, FIG. 1C illustrates a view taken along a plane across word lines of the 3D memory device of FIG. 1A, FIG. 1D illustrates a view taken along a plane across regions of the capacitor structures of the 3D memory device of FIG. 1A, FIG. 1E illustrates a view taken along a plane across isolation between transistor stacks of the 3D memory device of FIG. 1A, and FIG. 1F illustrates a view taken along a plane providing a top down view of the 3D memory device of FIG. 1A;

FIG. 2A provides an isometric view of an exemplary 3D memory device having laterally segmented capacitor structures, FIG. 2B illustrates a view taken along a plane across the transistor and capacitor of each memory cell of the 3D memory device of FIG. 2A, FIG. 2C illustrates a view taken along a plane across word lines of the 3D memory device of FIG. 2A, FIG. 2D illustrates a view taken along a plane across regions of the capacitor structures of the 3D memory device of FIG. 2A, FIG. 2E illustrates a view taken along a plane across isolation between transistor stacks of the 3D memory device of FIG. 2A, and FIG. 2F illustrates a view taken along a plane providing a top down view of the 3D memory device of FIG. 2A;

FIG. 3A provides an isometric view of an exemplary 3D memory device having vertically segmented capacitor structures.

FIG. 3B illustrates a view taken along a plane across the transistor and capacitor of each memory cell of the 3D memory device of FIG. 3A, FIG. 3C illustrates a view taken along a plane across word lines of the 3D memory device of FIG. 3A, FIG. 3D illustrates a view taken along a plane across regions of the capacitor structures of the 3D memory device of FIG. 3A, FIG. 3E illustrates a view taken along a plane across isolation between transistor stacks of the 3D memory device of FIG. 3A, and FIG. 3F illustrates a view taken along a plane providing a top down view of the 3D memory device of FIG. 3A;

FIG. 4A provides an isometric view of an exemplary 3D memory device having vertical plate lines, FIG. 4B illustrates a view taken along a plane across the transistor of each memory cell of the 3D memory device of FIG. 4A, FIG. 4C illustrates a view taken along a plane across word lines of the 3D memory device of FIG. 4A, FIG. 4D illustrates a view taken along a plane across plate line structures of the 3D memory device of FIG. 4A, FIG. 4E illustrates a view taken along a plane across isolation between transistor stacks of the 3D memory device of FIG. 4A, and FIG. 4F illustrates a view taken along a plane providing a top down view of the 3D memory device of FIG. 4A;

FIG. 5A provides an isometric view of an exemplary 3D memory device having horizontal plate lines, FIG. 5B illustrates a view taken along a plane across the transistor of each memory cell of the 3D memory device of FIG. 5A, FIG. 5C illustrates a view taken along a plane across word lines of the 3D memory device of FIG. 5A, FIG. 5D illustrates a view taken along a plane across plate line structures of the 3D memory device of FIG. 5A, FIG. 5E illustrates a view taken along a plane across isolation between transistor stacks of the 3D memory device of FIG. 5A, and FIG. 5F illustrates a view taken along a plane providing a top down view of the 3D memory device of FIG. 5A;

FIG. 6 is an illustrative diagram of a mobile computing platform employing a device having a 3D ferroelectric memory cell architecture; and

FIG. 7 is a functional block diagram of a computing device, all arranged in accordance with at least some implementations of the present disclosure.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Memory architectures and related structures are described herein related to three-dimensional ferroelectric memory having vertically stacked and laterally arrayed memory cells for improved memory density and performance.

As discussed, it is desirable to increase memory density and to improve memory device performance in terms of power usage, read and write operation speed, and reliability. In some embodiments, a three-dimensional (3D) array of memory cells is provided over a substrate having a lateral surface. As used herein, the term substrate indicates any underlying layers, support materials, and so on. Furthermore, the substrate may include active devices. The lateral surface of the substrate may be any surface that extends laterally (e.g., orthogonal to a build up direction) and may include any material, materials, or devices. Notably, the surface does not need to be a single material layer. The memory cells each include a transistor and a storage structure or mechanism. In some embodiments, individual ones of the memory cells include a transistor and at least a portion of a capacitor structure that includes a ferroelectric layer between first and second metal plates. In some embodiments, individual ones of the memory cells include a transistor having a ferroelectric gate dielectric layer and at least a portion of a metal plate line, which may also be characterized as source line. In such embodiments, the nature of the ferroelectric gate dielectric layer and, in particular, its hysteresis with respect to applied charge is leveraged to provide bit storage. Embodiments discussed herein provide a variety of advantages including the ability to directly control smaller blocks of the memory architecture, sharing of plate lines, and bit cell cost scaling without necessarily changing other structural dimensions. The memory arrays disclosed herein may provide dynamic random access memory (DRAM) solutions with improved packing density, read/write speed, and reliability. Other advantages will be evident in the following disclosure.

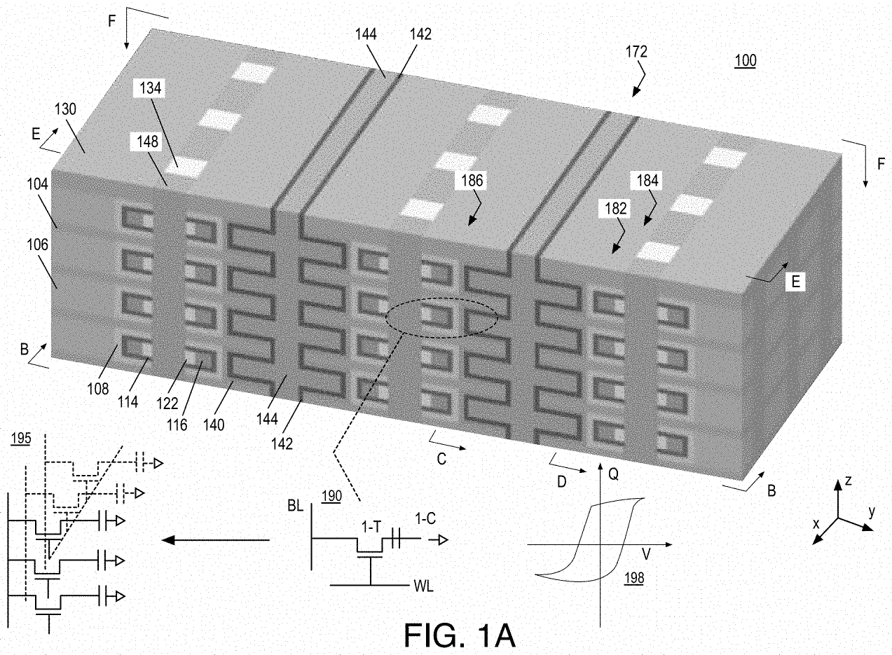

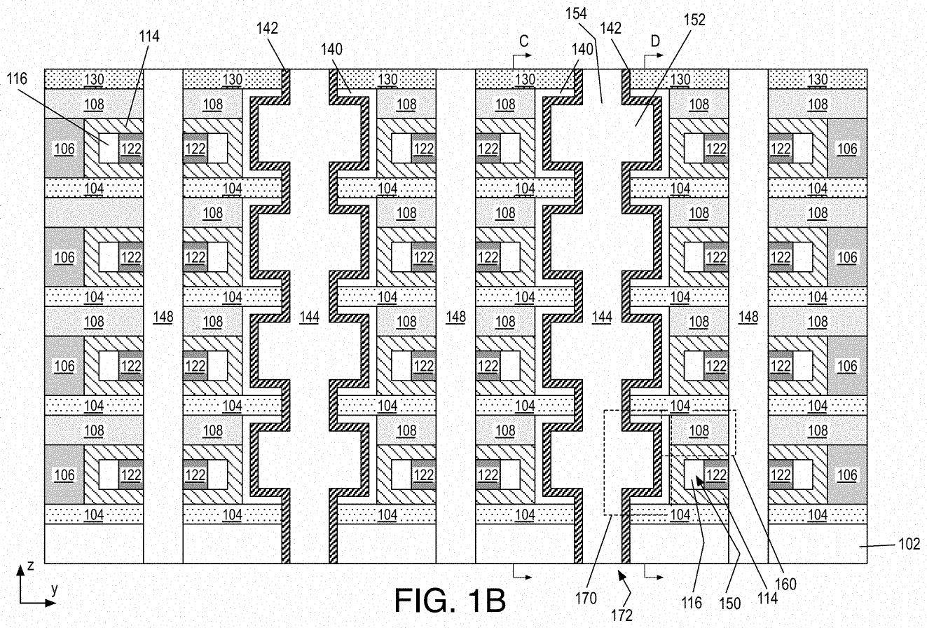

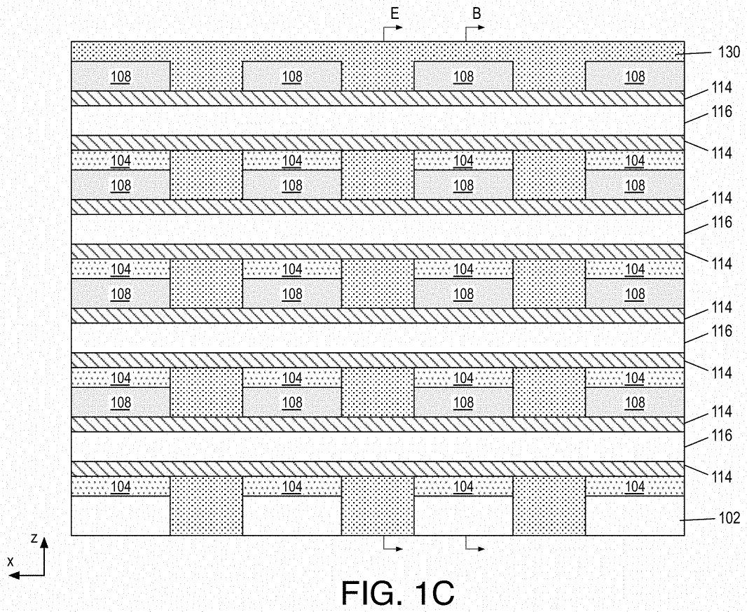

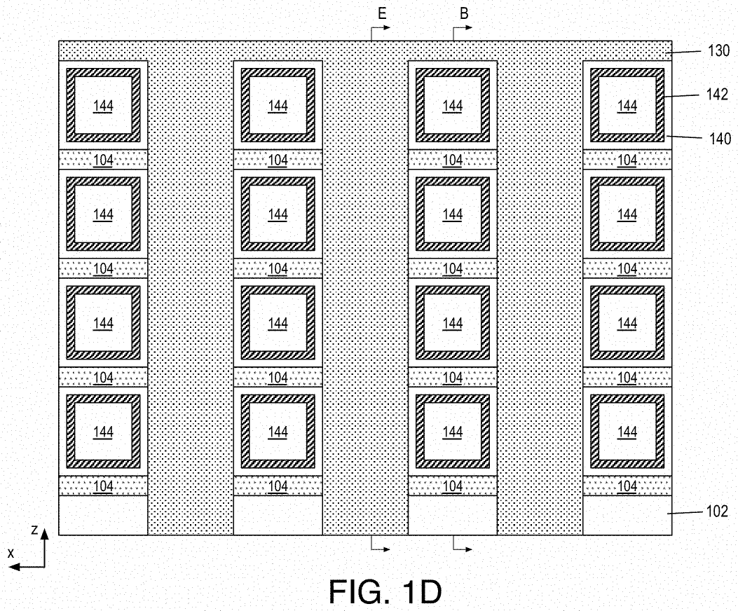

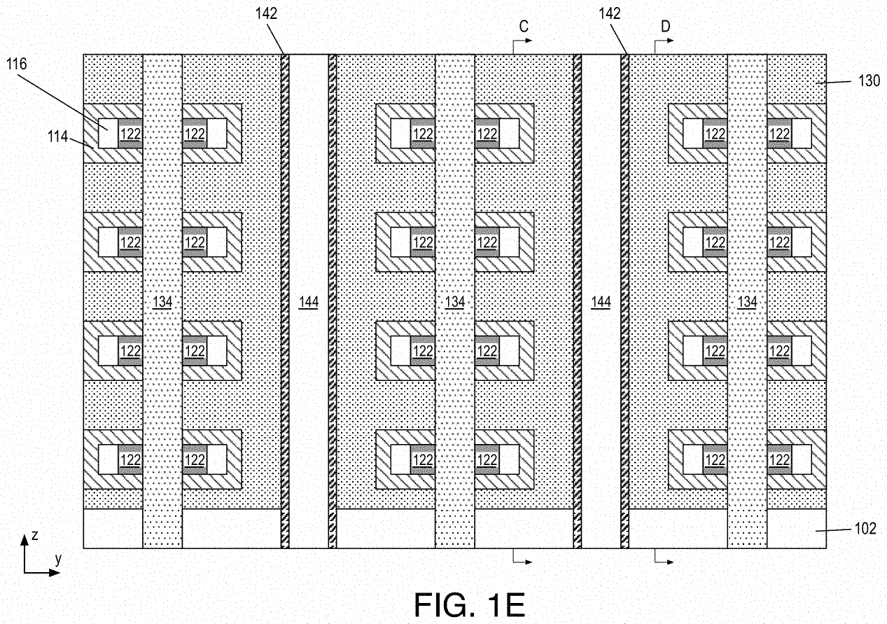

FIG. 1A provides an isometric view of an exemplary 3D memory device 100, arranged in accordance with at least some implementations of the present disclosure. FIG. 1B illustrates a view taken along plane B-B (i.e., across the transistor and capacitor of each memory cell), FIG. 1C illustrates a view taken along plane C-C (i.e., across word lines), FIG. 1D illustrates a view taken along plane D-D (i.e., across regions of the capacitor structures), FIG. 1E illustrates a view taken along plane E-E (i.e., across isolation between transistor stacks), and FIG. 1F illustrates a view taken along plane F-F (i.e., a top down view).

As shown, 3D memory device 100 includes a substrate 102, which may have a lateral surface along the x-y plane. Such lateral surface may be taken at any vertical position of substrate 102 such as a top surface. In some embodiments, substrate 102 includes monocrystalline silicon. However, other substrate materials as discussed herein may be used. Substrate 102 may include a device layer (e.g., transistor devices), metallization stack(s), or other device layers. As shown with respect to FIG. 1B, each of memory cells 150 may include a transistor 160 (or transistor portion) and a portion 170 of a capacitor structure 172 (or capacitor structure portion). Such memory cells 150 are stacked vertically and arrayed laterally within 3D memory device 100. Dielectric materials 106 may be provided at the perimeter of 3D memory device 100.

Notably, 3D memory device 100 provides a 3D array of memory cells 150 over substrate 102 such that individual ones of memory cells 150 each include transistor 160 and a portion 170 of capacitor structure 172 arranged horizontally with respect to one another. Portion 170 may also be characterized as a capacitor structure. In the following, description of one structure or component generally applies to others of 3D memory device 100, which are not labeled for the sake of clarity of presentation. Memory cells 150 are vertically stacked and laterally arrayed with respect to the lateral surface of substrate 102. Transistor 160 includes a channel structure 108 that extends substantially parallel to the lateral surface. Channel structure may be referred to as a channel material or, simply, a channel Channel structure 108 may include any suitable semiconductor material. In some embodiments, channel structure 108 is a thin film material that may be deposited at relatively low temperatures, within the thermal budgets imposed on back-end fabrication. In some embodiments, channel structure 108 is an amorphous, polycrystalline, or crystalline semiconductor material. In some embodiments, channel structure 108 is a group III-V material, silicon, germanium, silicon germanium, gallium arsenide, indium antimonide, indium gallium arsenide, gallium antimonide, tin oxide, indium gallium oxide (IGZO) or indium gallium zinc oxide (IGZO). Any of such materials may be deployed in amorphous, polycrystalline, or crystalline structures.

Transistor 160 also includes a gate dielectric layer 114 between channel structure 108 and corresponding word lines 116. Word lines 116, or portions thereof, act as gate electrodes for transistors 160. As shown with respect to FIG. 1A, in some embodiments, gate dielectric layer 114 and channel structure 108 are over a top, bottom, and side surface of word line 116. As shown with respect to FIG. 1B, in some embodiments, gate dielectric layer 114 is are over a top, bottom, and side surface of word line 116 while channel structure 108 is only over the top surface of word line 116. In some embodiments, a spacer 122 is between word line 116 and bit line 148.

As shown, channel structure 108 is adjacent and substantially orthogonal to word line 116 such that both channel structure 108 and word line 116 are substantially parallel to the lateral surface of substrate 102. As used herein, the terms vertical, horizontal, orthogonal, and parallel and the like are used with respect to their ordinary meaning with the component or structure being referenced extending in such directions along the greatest dimension of the component or structure (i.e., the length of the component or structure) Channel structure 108 extends between and contacts each of bit line 148 and portion 170 of capacitor structure 172.

Capacitor structure 172 includes inner capacitor plate 144 and outer capacitor plate 140 separated by capacitor ferroelectric layer 142. Capacitor ferroelectric layer 142 may include any suitable ferroelectric material. Ferroelectric layer 142 may be characterized as a ferroelectric dielectric material. As used herein, the term ferroelectric material indicates a material that has a spontaneous electric polarization that may be controlled by the application of an external electric field. In some embodiments, capacitor ferroelectric layer 142 includes lead, zirconium, titanium, and oxygen (e.g., lead zirconium titanate, Pb[ZrₓTi₁₋ₓ]O₃) In some embodiments, capacitor ferroelectric layer 142 includes barium, titanium, and oxygen (e.g., barium titanate, BaTiO₃). In some embodiments, capacitor ferroelectric layer 142 includes lead, titanium, and oxygen (e.g., lead titanate, PbTiO₃). In some embodiments, capacitor ferroelectric layer 142 includes barium, strontium, titanium, and oxygen (e.g., barium strontium titanate, BaSrTiO₃). Other ferroelectric materials may be employed.

As shown with respect to charge versus voltage graph 198, ferroelectric materials exhibit a hysteresis such that when a positive voltage is applied, a positive residual charge is maintained even as the voltage falls to zero. This residual charge is characterized as polarization. To remove the polarization, a negative voltage must be applied. Furthermore, the negative voltage may be used to provide a negative polarization, which is also maintained as the voltage again goes to zero. In capacitor structure 172 and other capacitor structures discussed herein, a differential voltage must be applied across the ferroelectric capacitor to polarize capacitor ferroelectric layer 142 (i.e., the ferroelectric material) either positively or negatively. This positive or negative polarity may then be read as 1 or 0. In the context of FIGS. 1A-1F, each of capacitor structures 172 is shared along word lines 116 and bit lines 148.

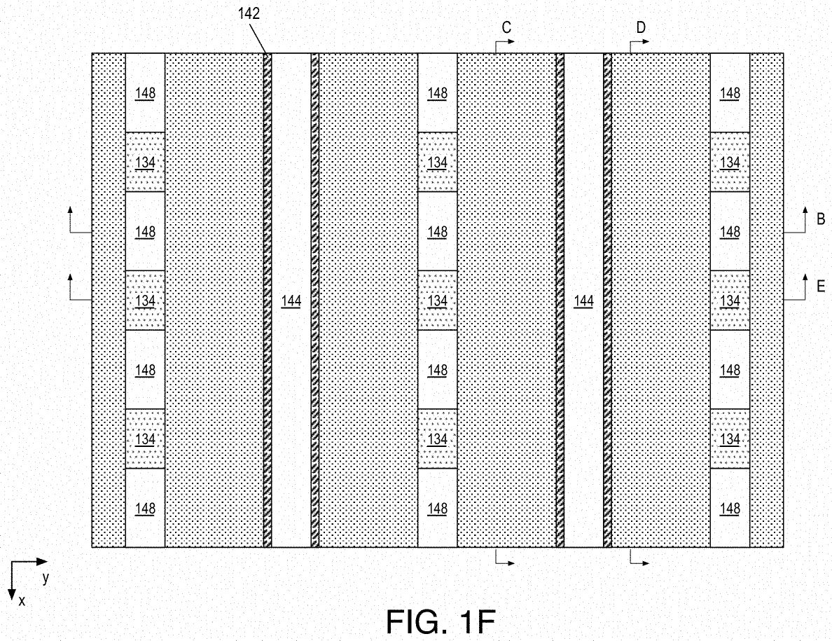

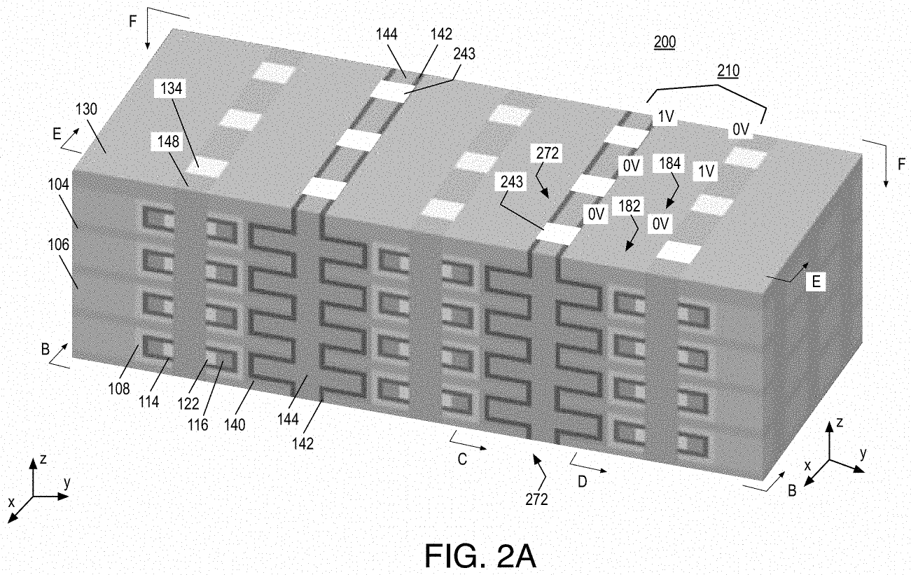

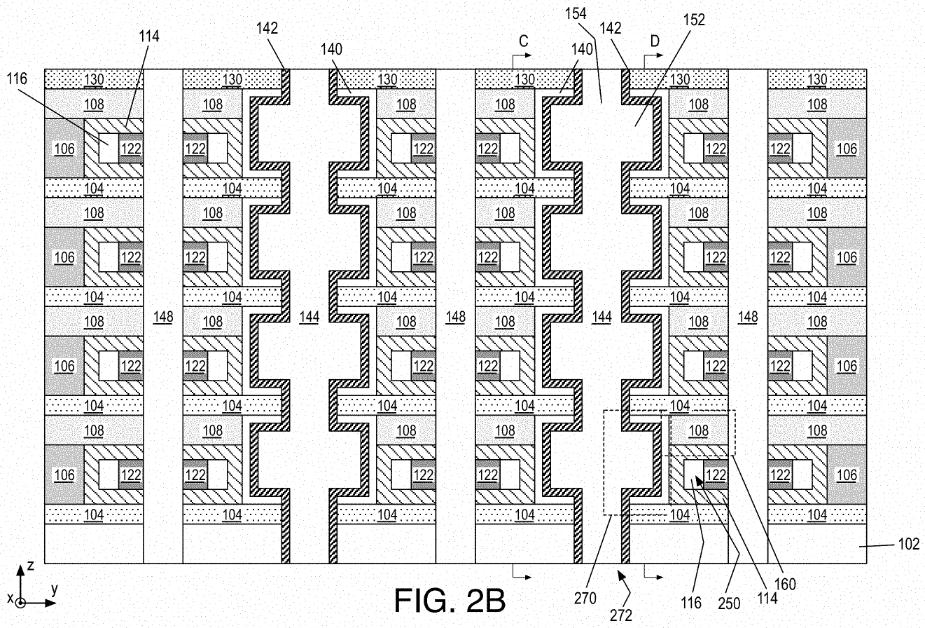

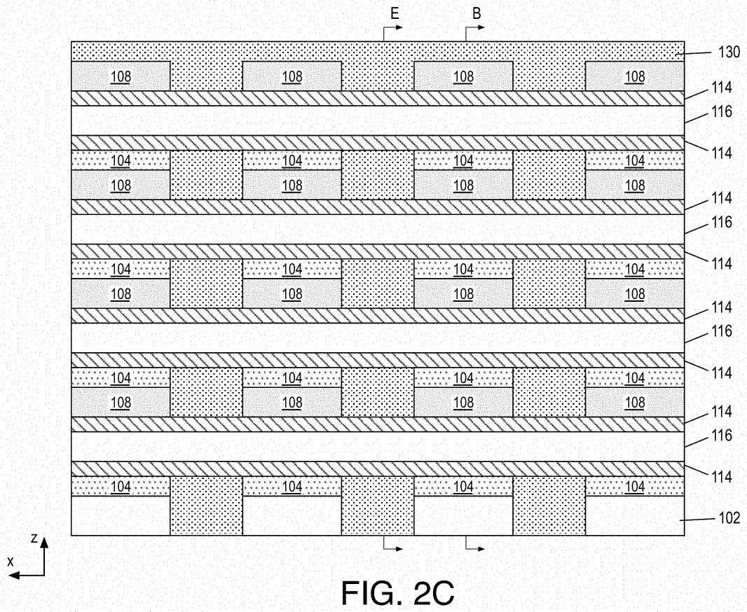

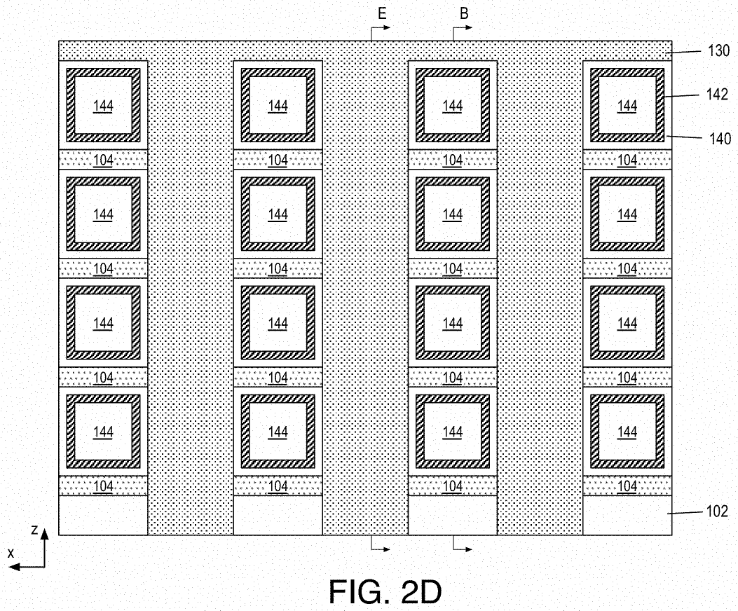

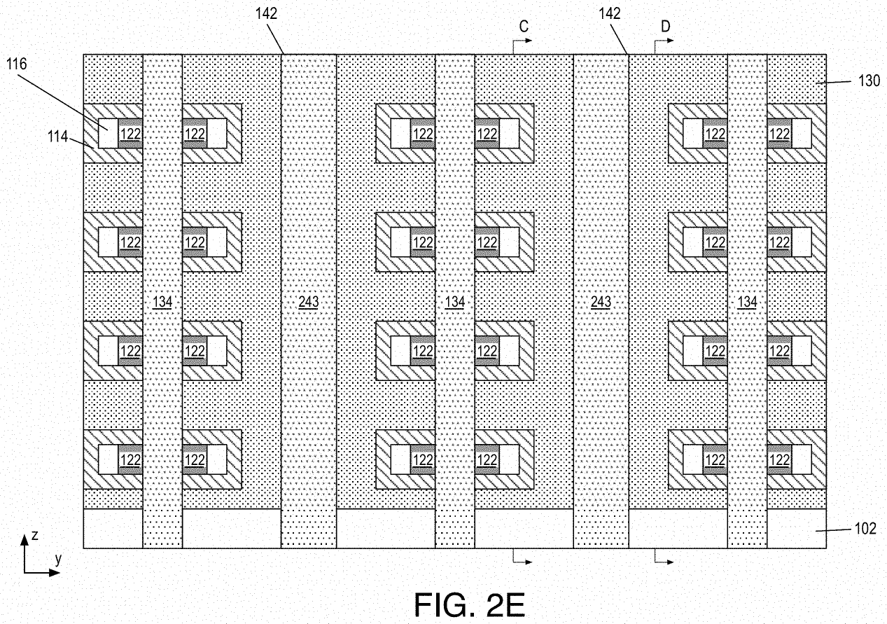

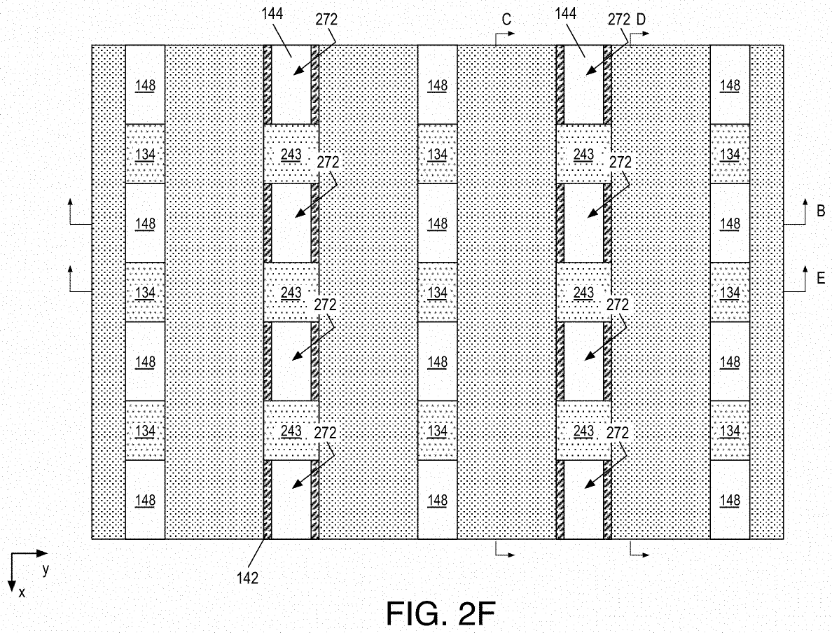

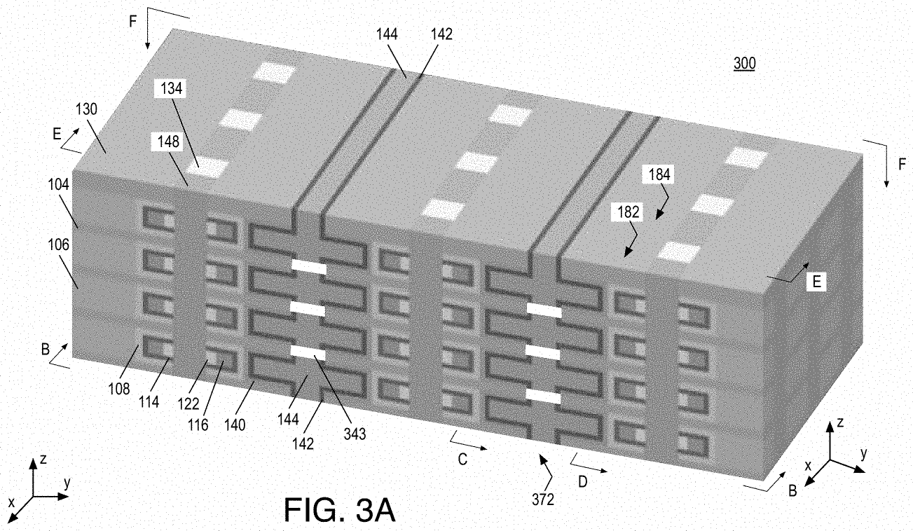

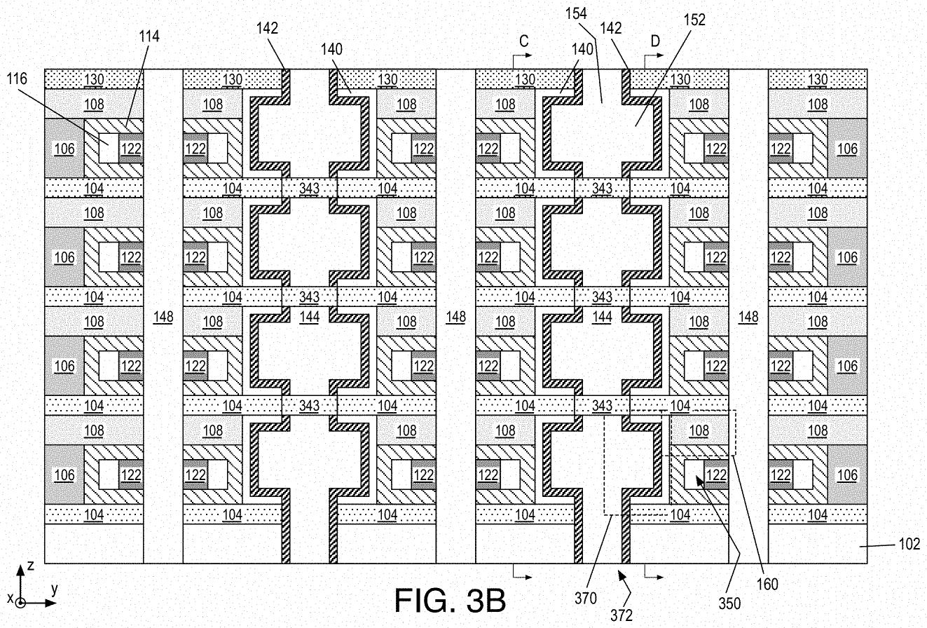

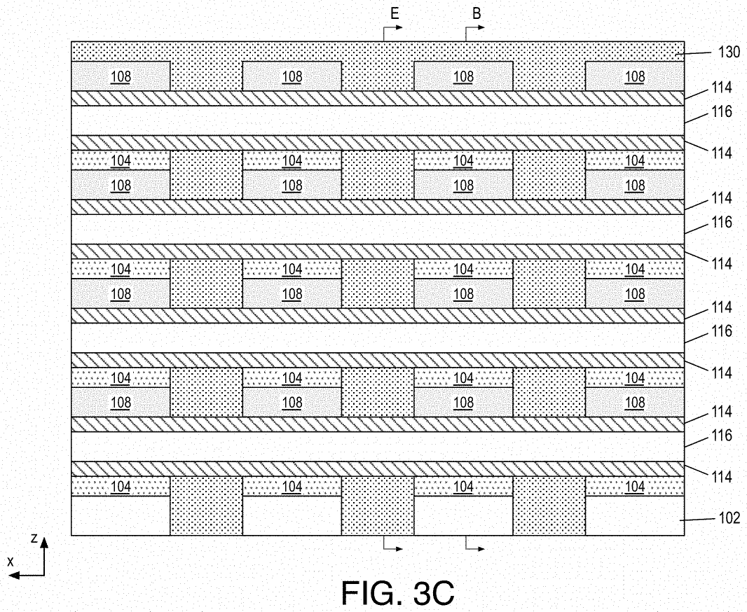

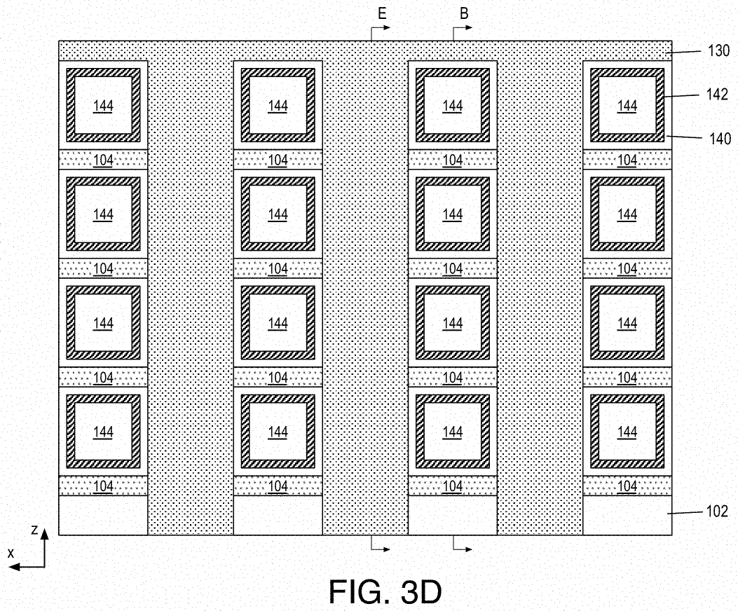

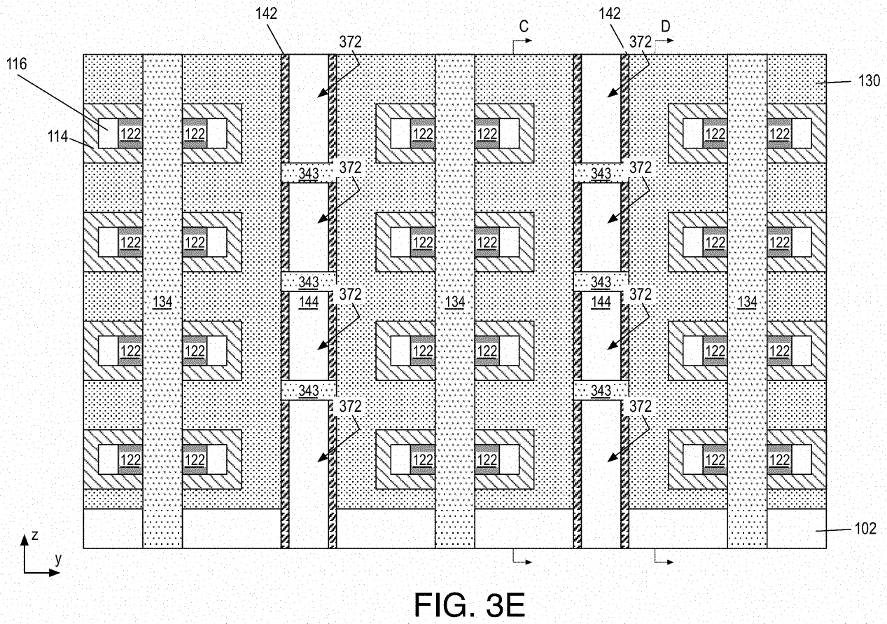

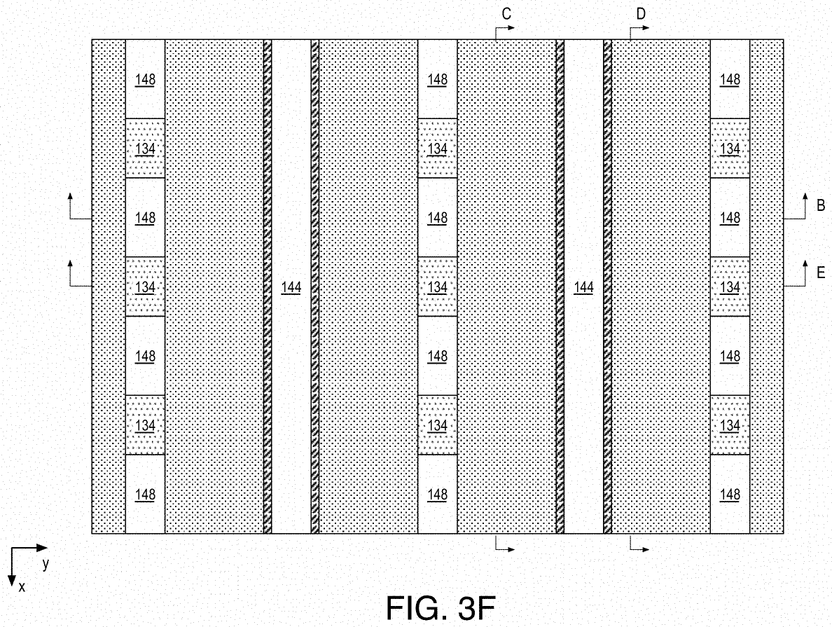

As shown via memory cell circuit 190 of FIG. 1A, such memory cells of 3D memory device 100 provides a one capacitor-one transistor (1C-1T) architecture such that each memory cell includes a capacitor as provided by portion 170 of capacitor structure 172 and a transistor as provided by transistor 160. The gate of transistor 160 is controlled via word line 116 and the source/drain are coupled to capacitor structure 172 and bit line 148. Furthermore, as shown via partial 3D array circuit 195, each word line 116 and each bit line 148 is coupled to an array of transistors (via gate and source/drain, respectively) to provide access to each memory cell in a block wise fashion. As discussed herein below with respect to FIGS. 2A-2F and FIGS. 3A-3F, in some embodiments, the deployment of capacitor ferroelectric layer 142 may allow for individual read and write access to each memory cell when the capacitor structures are segmented along either the bit line direction (i.e., FIGS. 2A-2F) or the word line direction (i.e., FIGS. 3A-3F).

With reference to FIGS. 1A and 1B, 3D memory device 100 includes a 3D array of memory cells 150 over substrate 102 such that individual ones of memory cells 150 include transistor 160 having channel structure 108 adjacent and orthogonal to word line 116 with channel structure 108 and word line 116 both being substantially parallel to the lateral surface of substrate 102. Individual ones of memory cells 150 further include at least a portion of capacitor structure 172 with capacitor structure 172 including capacitor ferroelectric layer 142 between capacitor plates 140, 144, such that channel structure 108 extends between and contacts bit line 148 and capacitor plate 140 and bit line 148 is substantially orthogonal to the lateral surface.

Capacitor plates 140, 144, word line 116, and bit line 148 may include any conductive material or materials such as metals or metal alloys such as copper, cobalt, tungsten, titanium, aluminum, ruthenium, or alloys of such materials. Furthermore, capacitor plate 144 may include optional regions 152 that extend laterally from trunk region 154. Regions 152 may be characterized as extension regions or structures, lateral regions or structures, or the like. Trunk region 154 may also be characterized as a trunk structure. For example, trunk region 154 may extend vertically and regions 152 may extend laterally therefrom to increase capacitance surface area and to offer other advantages. In some embodiments, channel structure 108 couples to capacitor structure 172 at a lateral region 152 that extends from trunk region 154.

Furthermore, each module or stack including channel structure 108, gate dielectric layer 114, word line 116 and spacer 122 may be separated vertically from another module or stack including the same components by a dielectric material 104. Dielectric material 104 may include any suitable insulator or isolation material such as carbon-doped oxide, silicon nitride, silicon oxide, or other carbides or nitrides (e.g., silicon carbide, silicon nitride doped with carbon, or silicon oxynitride). Similarly, spacer 122 may include any such materials.

As shown, in some embodiments, 3D memory device 100 includes a number of first memory cells 182 each accessed by one of bit lines 148 such that the memory cells are stacked vertically over the lateral surface of substrate 102. Capacitor structure 172 includes a same number of regions 152 extending laterally from trunk region 154 of capacitor structure 172 with each of regions 152 adjacent to a corresponding transistor 160 of individual ones of the first memory cells.

Furthermore, 3D memory device 100 includes a number of second memory cells 184 (i.e., in the negative x direction from first memory cells 182) each accessed by a second of bit lines 148 that are also stacked vertically over the lateral surface. Second memory cells 184 are laterally adjacent first memory cells 182 (i.e., in the negative x-direction). Regions 152 of capacitor structure 172 are each adjacent a corresponding transistor of individual ones of second memory cells 184 with the two bit lines being separated by dielectric material 134. Dielectric material 134 may include any material discussed with respect to dielectric material 104. Notably, the transistors of both first memory cells 182 and second memory cells 184 are coupled to different surface portions of the same regions 152 as capacitor structure 172 is a continuous structure therebetween.

In addition, 3D memory device 100 includes a number of third memory cells 186 (i.e., in the negative y-direction from first memory cells 182) each accessed by another bit lines 148 that are also stacked vertically over the lateral surface of substrate 102. Third memory cells 186 are laterally opposite capacitor structure 172 from first memory cells 182. As shown, second regions 152 of capacitor structure 172 extending from trunk region 154 (e.g., laterally opposite regions each extending from the same vertical portion of trunk region 154) are adjacent a corresponding transistor of individual ones of the third memory cells. As discussed, individual ones of regions 152 extend laterally opposite from trunk region 154 and parallel to the lateral surface to couple to individual ones of transistors 160 of first memory cells 182 and third memory cells 186.

Turning now to FIG. 1C, as shown in the across word lines view, word lines 116 extend in the x-direction to control multiple transistors 160 (i.e., arrayed along the x-direction) such that different regions of word lines 116 are separated from a channel structure 108 of each of transistors 160 by one of gate dielectric layers 114. Gate dielectric layers 114 may be, for example, silicon oxide, aluminum oxide, or a high-k dielectric, such as hafnium oxide. For example, the gate dielectric layers 114 may include elements such as hafnium, silicon, oxygen, titanium, tantalum, lanthanum, aluminum, zirconium, barium, strontium, yttrium, lead, scandium, niobium, or zinc. Examples of materials that may be used in the gate dielectric layers 114 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. Such word lines 116, gate dielectric layers 114, and channel structures 108 are isolated and separated from one another by dielectric material 104 and/or dielectric material 130. Dielectric material 130 may include any material discussed with respect to dielectric material 104 or sealant materials.

As shown with respect to FIG. 1D, which illustrates a view across regions 152 of capacitor structures 172, inner capacitor plate 144 is surrounded by capacitor ferroelectric layer 142, which is in turn surrounded by outer capacitor plate 140. It is noted that in a view moved in the negative y-direction from that of the view shown in FIG. 1D, vertically aligned regions 152 of individual ones of capacitor structures 172 are interconnected by trunk region 154. Capacitor plates 140, 144 may by any suitable conductive materials such as, for example, metal (i.e., copper, cobalt, tungsten, titanium, aluminum, ruthenium, alloys thereof, etc.). In some embodiments, capacitor plates 140, 144 are the same material. In some embodiments, capacitor plates 140, 144 deploy different materials.

FIG. 1E illustrates a view across isolation between transistor stacks. As shown, for transistor stacks that are adjacent one another in the y-direction, dielectric material 134 provides isolation between bit lines 148 (refer to FIG. 1A). Also as shown, isolation between channel structures 108 is provided in the same x-direction by providing dielectric material 130 between adjacent ones of channel structures 108 of transistors 160. Word lines 116 extend through the x-direction and are evident in the view of FIG. 1E. Similarly, spacers 122 and gate dielectric layers 114 extend in the x-direction.

Finally, the top down view of FIG. 1F shows the alternating bit lines 148 and dielectric materials 134 separating them. Furthermore, FIG. 1F illustrates the monolithic structure of inner capacitor plates 144 of capacitor structures 172. Notably, contact may be made via interconnects or wiring to each of bit lines 148, each of inner capacitor plates 144, as well as each of word lines 116 (not shown) to provide read and write access to 3D memory device 100.

As illustrated in FIGS. 1A-1F, memory cells 150 are arranged in vertical stacks or columns and rows (i.e., in the x-direction) with vertically adjacent memory cells 150 separated by an dielectric material 104 and laterally adjacent memory cells in the x-direction separated by dielectric material 130. Memory cells 150 in each vertical stack or column share one of bit lines 148 and, in addition each bit line 148 may be shared by memory cells 150 in two adjacent columns in the y-direction. For example, the number of memory cells 150 per bit line 148 may be twice the number of memory cells 150 in a particular column of memory cells 150. Individual ones of bit lines 148 in the x-direction are separated from one another by dielectric material 134.

The components and structures of 3D memory device 100 may be provided at any suitable dimensions. In some embodiments, a width (i.e., y-dimension) of bit lines 148 may be between 10 nanometers and 50 nanometers, a length (i.e., y-dimension) of channel 108 may be between 30 nanometers and 100 nanometers, a width (i.e., y-dimension) of capacitor plate 140 may be between 50 nanometers and 400 nanometers, a width (i.e., y-dimension) of trunk region 154 of capacitor plate 144 may be between 1 nanometer and 20 nanometers, a height (i.e., z-dimension) of region 152 may be between 10 nanometers and 100 nanometers, a height (i.e., z-dimension) of the dielectric material 104 may be between 10 nanometers and 20 nanometers, a height (i.e., z-dimension) of channel structure 108 may be between 5 nanometers and 50 nanometers, a thickness of capacitor ferroelectric layer 142 may be between 2 nanometers and 5 nanometers, a height of word line 116 (i.e., z-dimension) may be between 5 nanometers and 20 nanometers, and a thickness of a gate dielectric layer 114 may be between 2 nanometers and 20 nanometers. Other dimensions may be used.

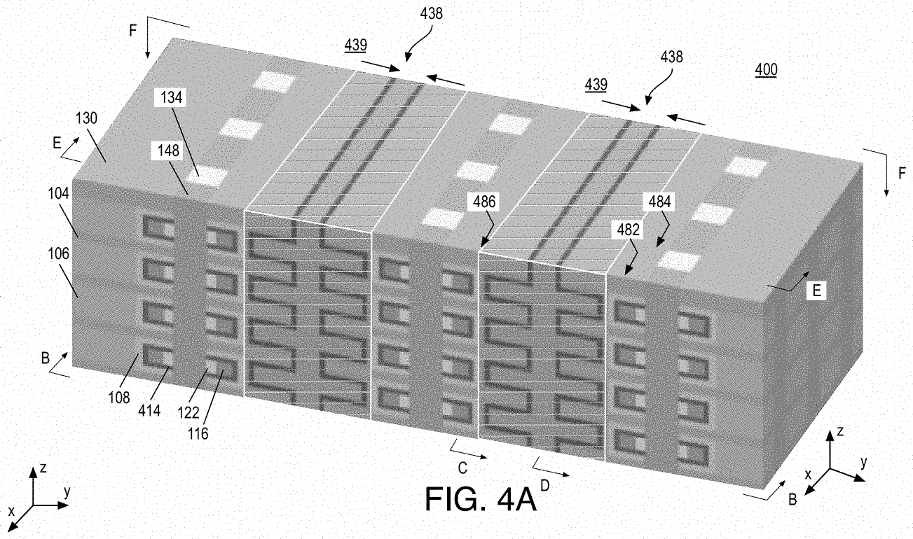

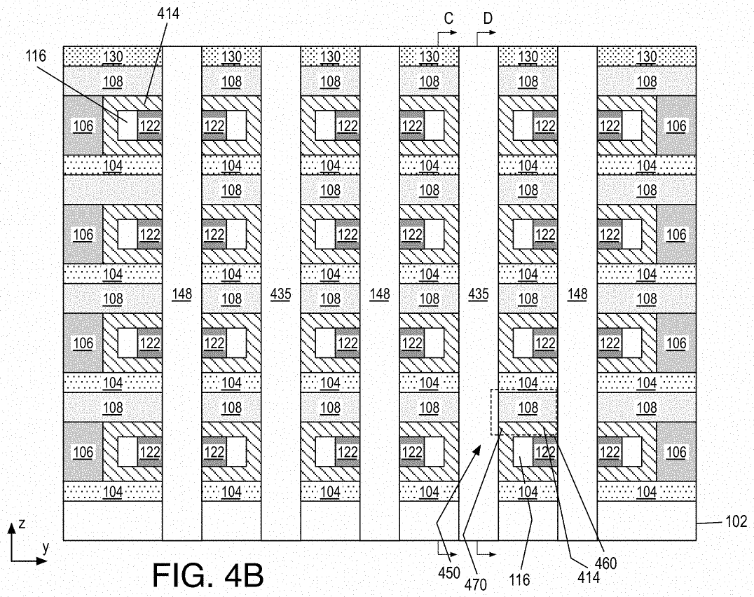

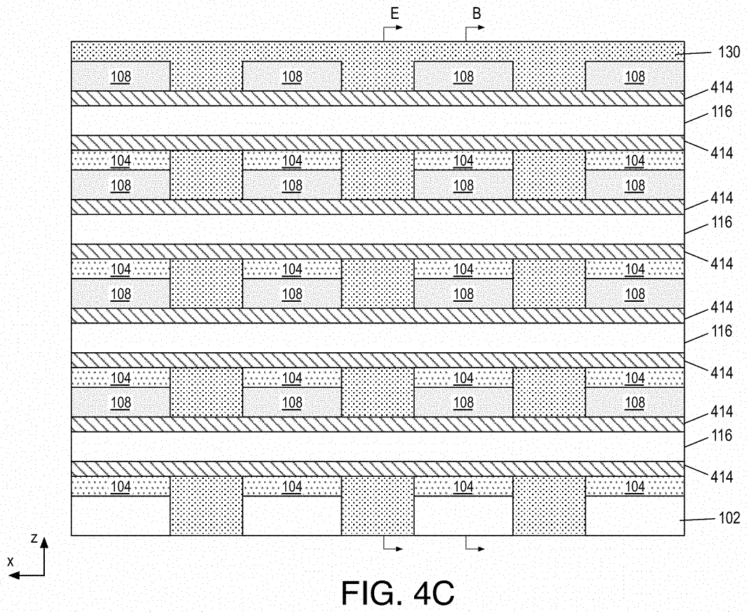

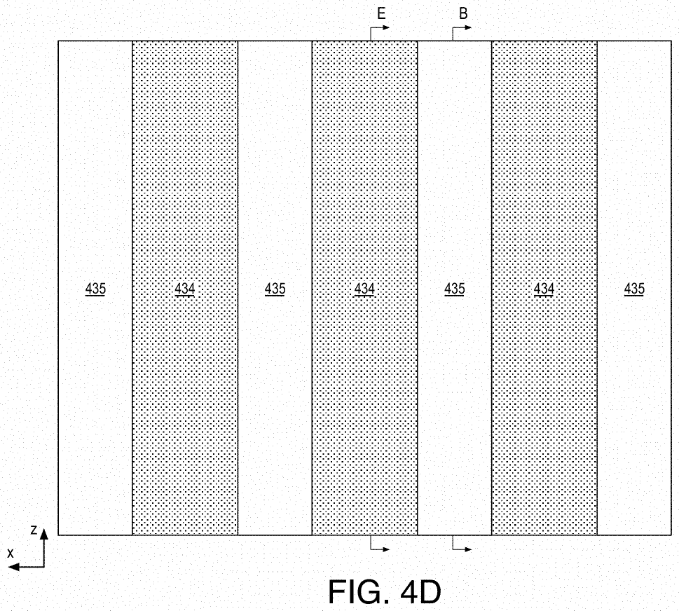

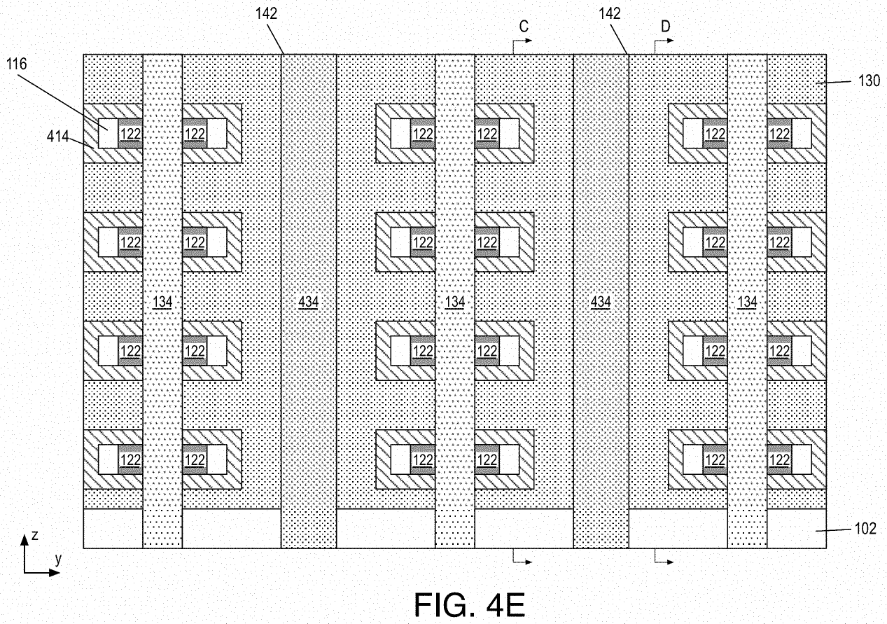

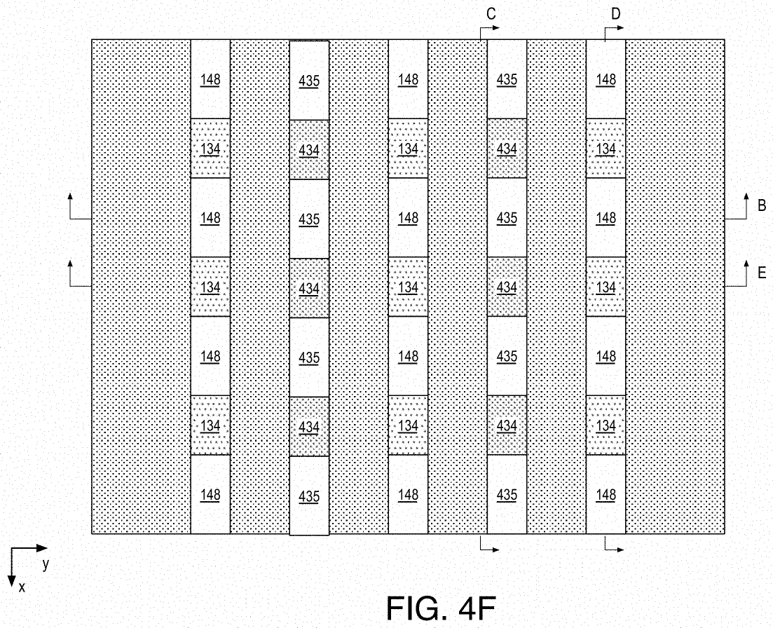

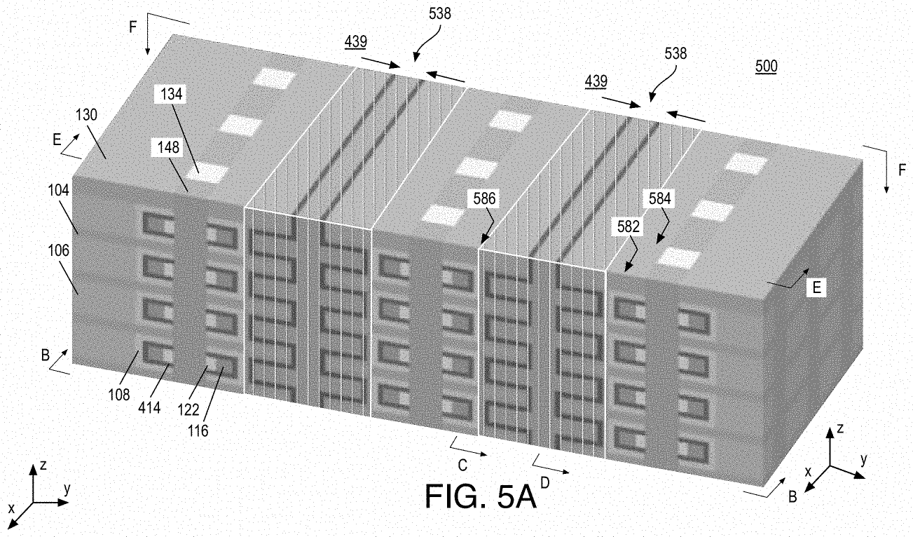

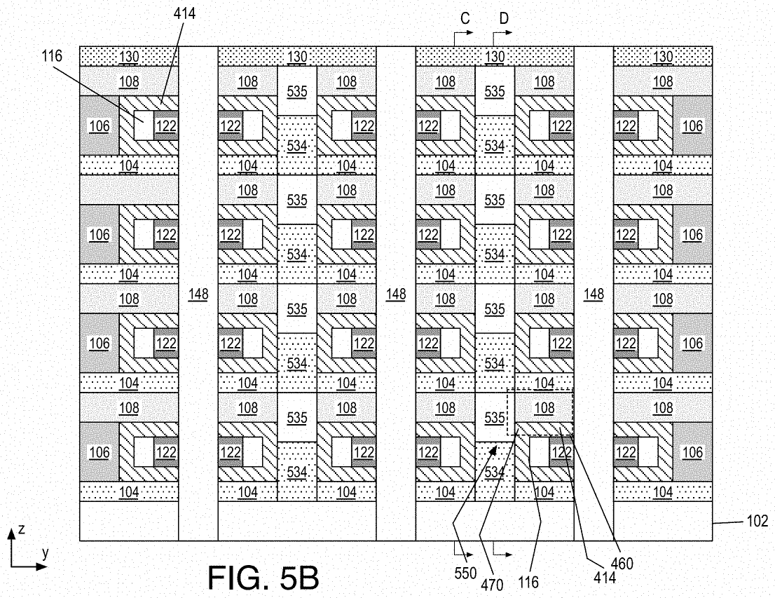

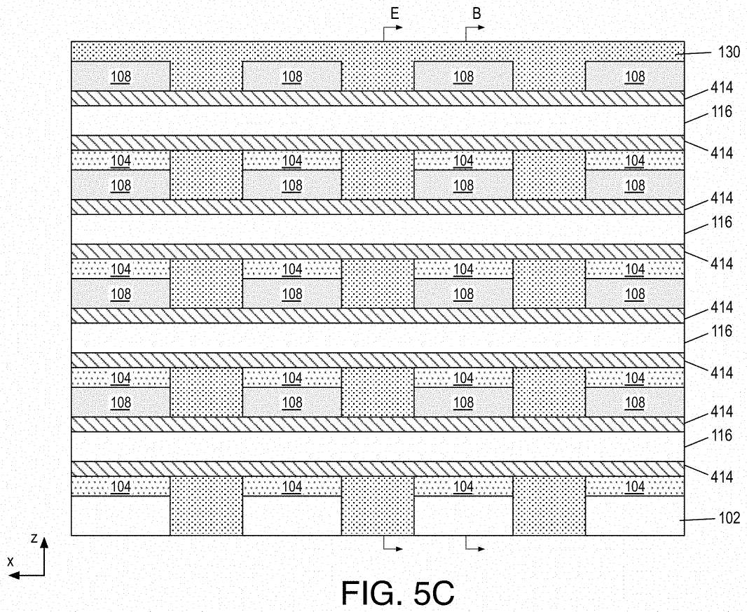

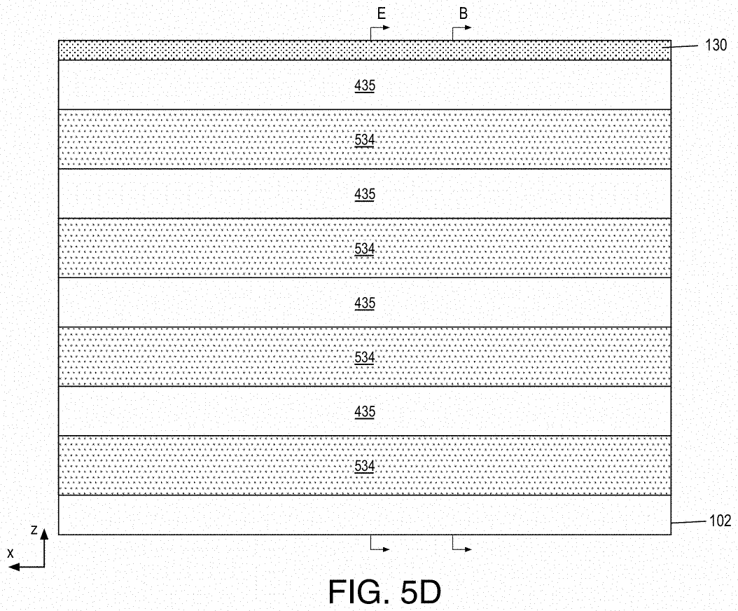

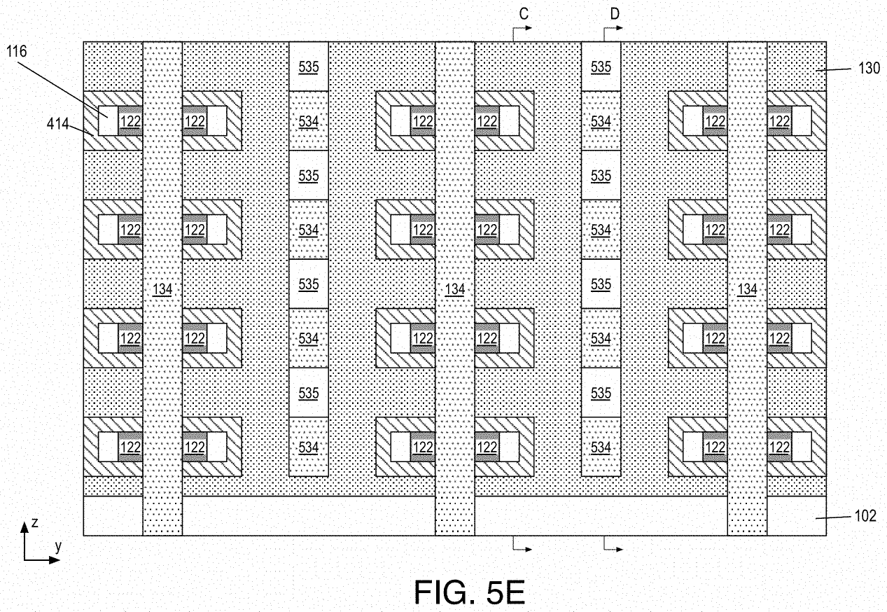

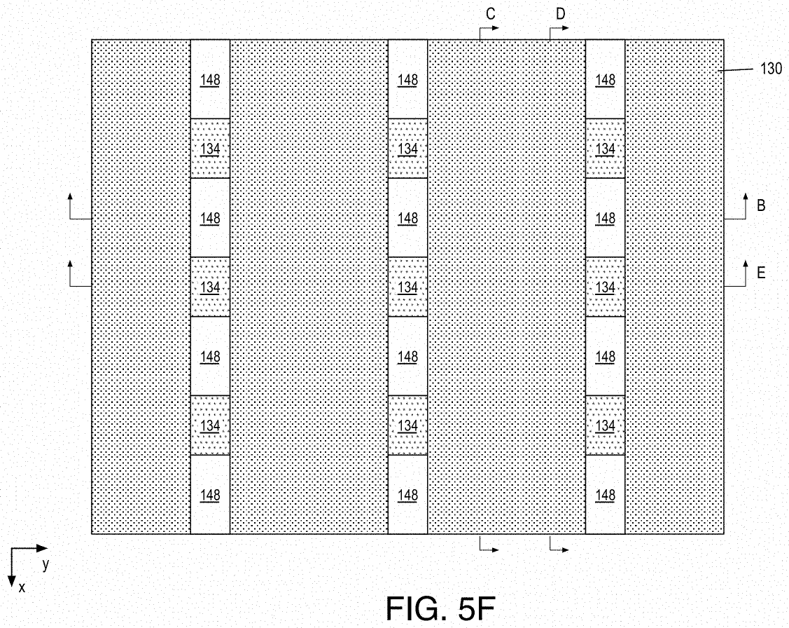

Turning now to FIGS. 2A-2F and then to FIGS. 3A-3F, 3D memory device memory architectures are discussed that provide increased granularity with respect to read and write access to each memory cell of the 3D array. Such increased access is achieved by providing lateral segmenting between capacitor structures (i.e., FIGS. 2A-2F) or by providing vertical segmentation between capacitor structures (i.e., FIGS. 3A-3F) as discussed further herein below. Such segmentation allows greater access and is enabled by the deployment of capacitor ferroelectric layer 142. In the discussion of the following FIGS. 2A-2F and 3A-3F as well as FIGS. 4A-4F and 5A-5F, like numerals are used to represent like components or structures and such components or structures may have any characteristics (e.g., dimensions, materials, etc.) discussed elsewhere herein.

FIG. 2A provides an isometric view of an exemplary 3D memory device 200, arranged in accordance with at least some implementations of the present disclosure. FIG. 2B illustrates a view taken along plane B-B (i.e., across the transistor and capacitor of each memory cell), FIG. 2C illustrates a view taken along plane C-C (i.e., across word lines), FIG. 2D illustrates a view taken along plane D-D (i.e., across regions of the capacitor structures), FIG. 2E illustrates a view taken along plane E-E (i.e., across isolation between transistor stacks), and FIG. 2F illustrates a view taken along plane F-F (i.e., a top down view).

3D memory device 200 includes substrate 102 having a lateral surface along the x-y plane. 3D memory device 200 includes an array of memory cells 250. With reference to FIG. 2B, each of memory cells 250 includes transistor 160 (or transistor portion) and a portion 270 of a capacitor structure 272 (or capacitor structure portion). Such memory cells 250 are stacked vertically and arrayed laterally within 3D memory device 100. Dielectric materials 106 may be provided at the perimeter of 3D memory device 200.

3D memory device 200 provides 3D array of memory cells 250 over substrate 102 such that individual ones of memory cells 250 each include transistor 160 and at least portion 270 of capacitor structure 272 arranged horizontally with respect to one another. Portion 270 may also be characterized as a capacitor structure. Notably, in contrast to 3D memory device 100, each capacitor structure 272 is separated from another of capacitor structures 272 in the lateral x-dimension by dielectric material 243. Dielectric material 243 may include any suitable insulator or isolation material such as carbon-doped oxide, silicon nitride, silicon oxide, or other carbides or nitrides (e.g., silicon carbide, silicon nitride doped with carbon, or silicon oxynitride). In some embodiments, dielectric material 243 is the same material as dielectric material 134.

Memory cells 250 are vertically stacked and laterally arrayed with respect to the lateral surface of substrate 102. Transistor 160 includes channel structure 108 extending parallel to the lateral surface of substrate 102 from portion 270 to bit line 148. At least a portion of gate dielectric layer 114 is between and in contact with channel structure 108 and a corresponding one of word lines 116, which gates the corresponding ones of transistors 160. In some embodiments, as shown in FIG. 2A, gate dielectric layer 114 and channel structure 108 are over a top, bottom, and side surface of word line 116 (i.e., each having a C shaped profile). In some embodiments, as shown in FIG. 2B, gate dielectric layer 114 is are over a top, bottom, and side surface of word line 116 (i.e., having a C shaped profile in the y-z plane) while channel structure 108 is only over the top surface of word line 116 (i.e., having a linear profile in the y-z plane). Spacer 122 may be provided between word line 116 and bit line 148. Channel structure 108 is adjacent and substantially orthogonal to word line 116 (i.e., channel structure 108 extends along the y-direction and word line 116 extends along the x-direction) such that both channel structure 108 and word line 116 are substantially parallel to the lateral surface of substrate 102 (i.e., parallel t the x-y plane).

Each of capacitor structures 272 includes inner capacitor plate 144 and outer capacitor plate 140 separated by capacitor ferroelectric layer 142. As discussed, capacitor ferroelectric layer 142 may include lead, zirconium, titanium, and oxygen (e.g., lead zirconium titanate, Pb[ZrₓTi₁₋ₓ]O₃), barium, titanium, and oxygen (e.g., barium titanate, BaTiO₃), lead, titanium, and oxygen (e.g., lead titanate, PbTiO₃), barium, strontium, titanium, and oxygen (e.g., barium strontium titanate, BaSrTiO₃), or other ferroelectric material. As discussed with respect to FIG. 1A, such materials exhibit a hysteresis such that when a positive or negative voltage is applied, a positive or negative polarization is maintained even as the voltage returns to zero and the positive or negative polarity may then be read as 1 or 0. In the context of FIGS. 2A-2F, each of capacitor structures 272 is shared only along a single one of bit lines 148. In contrast to 3D memory device 100, capacitor structures 272 (i.e., plate lines) are cut along bit lines 148 so that individual bits can write polarized data on their own capacitor structure. In the context of FIGS. 3A-3F, each of capacitor structures 372 is shared only along a single one of word lines 116, providing a similar effect.

Data writing examples 210 of FIG. 2A illustrate example bit line 148 writing along a corresponding capacitor structure of capacitor structures 272. The same aim may be achieved, by providing separated capacitor structures 372 as shown in FIGS. 3A-3F. Notably, one of data writing examples 210 provides 1V on the capacitor structure (or plate line) and 0V on the bit line to write a value of 1 (for example), another of data writing examples 210 provides 0V on the plate line and 1V on the bit line to write a value of 0 (for example), and yet another of data writing examples 210 provides 0V on the plate line and the bit line such that nothing is written and the polarization of the ferroelectric material is maintained. Thereby, segmentation into capacitor structures 272 provides greater granularity in the access of memory cells 250. For example, such differentials along the memory cells 250 are only achievable through capacitor structure segmentation.

3D memory device 200 provides a 1C-1T architecture with each memory cell having a capacitor (e.g., portion 270 of capacitor structure 272) and a transistor (e.g., transistor 160). The gate of transistor 160 is controlled via word line 116 and the source/drain are coupled to capacitor structure 272 and bit line 148. The 1C-1T architecture provides advantages of accessing memory cells at a greater granularity.

Turning now to FIG. 2C, as shown in the across word lines view, word lines 116 extend in the x-direction to control multiple transistors 160 (i.e., arrayed along the x-direction) such that different regions of word lines 116 are separated from a channel structure 108 of each of transistors 160 by one of gate dielectric layers 114. Such word lines 116, gate dielectric layers 114, and channel structures 108 are isolated and separated from one another by dielectric material 104 and/or dielectric material 130. As shown with respect to FIG. 2D, which illustrates a view across regions 152 of capacitor structures 272, inner capacitor plate 144 is surrounded by capacitor ferroelectric layer 142, which is in turn surrounded by outer capacitor plate 140. Notably, capacitor structures 272 may deploy regions 152 and trunk region 154 in a similar manner to capacitor structures 172.

FIG. 2E illustrates a view across isolation between transistor stacks. As shown, for transistor stacks that are adjacent one another in the y-direction, dielectric material 134 provides isolation between bit lines 148 (refer to FIG. 2A) and isolation between channel structures 108 is provided in the same x-direction by providing dielectric material 130 between adjacent ones of channel structures 108 of transistors 160. Word lines 116, spacers 122 and gate dielectric layers 114 extend through the x-direction and are evident in the view of FIG. 2E. Furthermore, as shown, dielectric material 243 is provided extending between laterally adjacent (in the x-direction) ones of capacitor structures 272. Thereby, dielectric materials 134, 243 provide lateral isolation between bit lines 148 and capacitor structures 272, respectively, such that access may be independently made in bit line-capacitor structure pairs for improved granularity of memory cell access as discussed above.

In the top down view of FIG. 2F bit lines 148 and dielectric materials 134 separating them are alternated and, in a similar manner, alternating capacitor structures 272 and dielectric materials 243 provide differential access to plate lines for each bit line. Contact may be made via interconnects or wiring to each of bit lines 148, each of capacitor structures 272, as well as each of word lines 116 (not shown) to provide read and write access to 3D memory device 200.

As illustrated in FIGS. 2A-2F, memory cells 250 are provided over substrate 102 such that individual ones of memory cells 250 include transistor 160 having channel structure 108 adjacent and orthogonal to word line 116 such that channel structures 108 and word lines 116 are substantially parallel to a lateral surface of substrate 102. Individual ones of memory cells 250 also include at least portion 270 of one of capacitor structures 272 that has ferroelectric layer 142 between first and second capacitor plates 140, 144 such that channel structure 108 extends between and contacts one of bit lines 148 and outer capacitor plate 140, with bit line 148 being orthogonal to the lateral surface of substrate 102. First memory cells 182, each accessed by one of bit lines 148, are stacked vertically over the lateral surface of substrate. Second memory cells 184, each accessed by another of bit lines 148, are stacked vertically over the lateral surface of substrate and laterally adjacent from first memory cells 182. Notably, second memory cells 184 access a different one of capacitor structures 272 than is accessed by first memory cells 182 due to the corresponding ones of capacitor structures 272 being separated by dielectric material 243. Such word lines 116, bit lines 148, and separated capacitor structures 272 provide increased granularity for access to each of memory cells 250.

Turning now to FIGS. 3A-3F, vertical segmentation between capacitor structures is provided such that capacitor structures are vertically stacked and separated for improved access to memory cells of the 3D memory architecture.

FIG. 3A provides an isometric view of an exemplary 3D memory device 300, arranged in accordance with at least some implementations of the present disclosure. FIG. 3B illustrates a view taken along plane B-B (i.e., across the transistor and capacitor of each memory cell), FIG. 3C illustrates a view taken along plane C-C (i.e., across word lines), FIG. 3D illustrates a view taken along plane D-D (i.e., across regions of the capacitor structures), FIG. 3E illustrates a view taken along plane E-E (i.e., across isolation between transistor stacks), and FIG. 3F illustrates a view taken along plane F-F (i.e., a top down view).

3D memory device 200 includes an array of memory cells 350 over substrate 102, which has a lateral surface along the x-y plane. With reference to FIG. 3B, each of memory cells 350 may include transistor 160 (or transistor portion) and a portion 370 of a capacitor structure 372 (or capacitor structure portion). Memory cells 350 are stacked vertically and arrayed laterally within 3D memory device 300. As shown, individual ones of memory cells 350 include transistor 160 and portion 370 of capacitor structure 372 such that, in contrast to 3D memory device 100, each capacitor structure 372 is separated from another of capacitor structures 272 in the vertical z-dimension by dielectric material 343. Dielectric material 343 may include any suitable insulator or isolation material such as carbon-doped oxide, silicon nitride, silicon oxide, or other carbides or nitrides (e.g., silicon carbide, silicon nitride doped with carbon, or silicon oxynitride). In some embodiments, dielectric material 343 is the same material as dielectric material 134.

Memory cells 350 are vertically stacked and laterally arrayed with respect to the lateral surface of substrate 102. Channel structure 108 of transistor 160 extends parallel to the lateral surface from portion 370 to bit line 148. At least a portion of gate dielectric layer 114 is between and in contact with channel structure 108 and a corresponding one of word lines 116, which gates the corresponding ones of transistors 160. Gate dielectric layer 114 and channel structure 108 may both have C shaped profiles or gate dielectric layer 114 may have a C shaped profile and channel structure 108 may have a linear profile (i.e., with such profiles being in the y-z plane).

Each of capacitor structures 372 includes inner capacitor plate 144 and outer capacitor plate 140 separated by capacitor ferroelectric layer 142. Capacitor ferroelectric layer 142 may include lead, zirconium, titanium, and oxygen (e.g., lead zirconium titanate, Pb[ZrₓTi₁₋ₓ]O₃), barium, titanium, and oxygen (e.g., barium titanate, BaTiO₃), lead, titanium, and oxygen (e.g., lead titanate, PbTiO₃), barium, strontium, titanium, and oxygen (e.g., barium strontium titanate, BaSrTiO₃), or other ferroelectric material. In the context of FIGS. 3A-3F, each of capacitor structures 372 is shared only along a single one of word lines 116. In contrast to 3D memory device 100, capacitor structures 372 (i.e., plate lines) are cut along word lines 116 so that individual bits can write polarized data on their own capacitor structure. Such a configuration provides higher granularity access to memory cells 350 in a manner similar to that discussed with respect to memory cells 250 and, in particular, to data writing examples 210. For example, segmentation into capacitor structures 372 provides greater granularity in the access of memory cells 350.

As with 3D memory devices 100, 200, 3D memory device 200 provides a 1C-1T architecture with each memory cell having a capacitor (e.g., portion 370 of capacitor structure 372) and a transistor (e.g., transistor 160). The gate of transistor 160 is controlled via word line 116 and the source/drain are coupled to capacitor structure 372 and bit line 148. Notably, in 3D memory device 200 laterally adjacent transistors 160 along the x-direction contact the same one of capacitor structures 372 while vertically adjacent transistors 160 (i.e., along the z-direction) contact separate ones of capacitor structures 372.

As shown in FIG. 3C, in an across word lines view, word lines 116 extend in the x-direction to control multiple transistors 160 (i.e., arrayed along the x-direction) such that different regions of word lines 116 are separated from a channel structure 108 of each of transistors 160 by one of gate dielectric layers 114. Such word lines 116, gate dielectric layers 114, and channel structures 108 are isolated and separated from one another by dielectric material 104 and/or dielectric material 130. Each of such word lines 116 is to access a same one of capacitor structures 372. That is, capacitor structures 372 and word lines 116 are each separated vertically from other ones of capacitor structures 372 and word lines 116, respectively. As shown with respect to FIG. 3D, illustrating a view across regions 152 of capacitor structures 372, inner capacitor plate 144 is surrounded by capacitor ferroelectric layer 142, which is in turn surrounded by outer capacitor plate 140. Capacitor structures 372 may deploy regions 152 while trunk region 154 may be segmented to isolate vertically adjacent ones of capacitor structures 372. It is noted that in a view moved in the negative y-direction from that of the view shown in FIG. 3D, trunk regions 154 are separated by portions of dielectric material 343 in a manner similar to that of dielectric material 104.

FIG. 3E illustrates a view across isolation between transistor stacks. FIG. 3E also illustrates the isolation between vertically adjacent ones of capacitor structures 372 as provided by dielectric material 134. As shown, for transistor stacks that are adjacent one another in the y-direction, dielectric material 134 provides isolation between bit lines 148 (refer to FIG. 3A) and isolation between channel structures 108 is provided in the same x-direction by providing dielectric material 130 between adjacent ones of channel structures 108 of transistors 160. Word lines 116, spacers 122 and gate dielectric layers 114 extend through the x-direction and are evident in the view of FIG. 3E. Furthermore, as shown, dielectric material 343 is provided extending between vertically adjacent (in the z-direction) ones of capacitor structures 372. Thereby, vertical isolation is provided between word lines 116 as well as capacitor structures 372 such that access may be independently made in word line-capacitor structure pairs for improved granularity of memory cell access as discussed herein.

In the top down view of FIG. 3F, bit lines 148 and dielectric materials 134 separating them are alternated. Furthermore, top down access to inner capacitor plates 144 of the top capacitor structures of capacitor structures 372 is provided. Lower capacitor structures 372 may be accessed outside of the view shown in FIG. 3F. For example, contact may be made via interconnects or wiring to each of bit lines 148, each of capacitor structures 372, as well as each of word lines 116 (not shown) to provide read and write access to 3D memory device 300.

In the embodiments discussed with respect to 3D memory devices 100, 200, 300, for each memory cell, a transistor and a capacitor structure are provided. The transistor provides access and switching with respect to the capacitor structure, which provides a storage medium. In the following embodiments, as discussed with respect to FIGS. 4A-4F and 5A-5F, the capacitor structure is replaced by a plate line (which may also be characterized as a source line) and the gate dielectric material of the transistor is replaced with a ferroelectric material (i.e., the transistor includes a ferroelectric gate dielectric layer). In contrast to using a capacitor structure to provide bit storage, the ferroelectric gate dielectric layer of the transistor is polarized. Such polarization may be detected as a 1 or 0. For example, to program the ferroelectric gate dielectric layer, a voltage differential is applied between a word line and a plate line. To provide access to each memory cell, therefore, the plate lines must be segmented along the bit lines (as shown in FIGS. 4A-4F) or along the word lines (as shown in FIGS. 5A-5F).

FIG. 4A provides an isometric view of an exemplary 3D memory device 400, arranged in accordance with at least some implementations of the present disclosure. FIG. 4B illustrates a view taken along plane B-B (i.e., across the transistor of each memory cell), FIG. 4C illustrates a view taken along plane C-C (i.e., across word lines), FIG. 4D illustrates a view taken along plane D-D (i.e., across plate line structures), FIG. 4E illustrates a view taken along plane E-E (i.e., across isolation between transistor stacks), and FIG. 4F illustrates a view taken along plane F-F (i.e., a top down view).

As shown in FIG. 4A, in 3D memory device 400, a capacitor structure is replaced by vertical plate line structures 438, which are detailed in FIGS. 4B-4F. Notably, as shown with respect to arrows 439, vertical plate line structures 438 offer reduced lateral width (i.e., in the y-direction) for 3D memory device 400. Other advantages of 3D memory device 400 will be evident from the following discussion.

3D memory device 400 includes substrate 102, which may have a lateral surface along the x-y plane as discussed herein. As shown with respect to FIG. 4B, each of memory cells 450 may include a transistor 460 (or transistor portion) and a memory structure 470 as provided by the ferroelectric material of ferroelectric gate dielectric 414 of transistor 460. That is, the functionality of memory structure 470 is provided by ferroelectric gate dielectric 414, which is also a component of transistor 460. Each of memory cells 450 may also include a portion of a plate line 435. Plate lines 435 extend vertically with respect to the lateral surface (i.e., in the z-direction) and are separated by dielectric material 434 in the same manner bit lines 148 extend vertically from the lateral surface (i.e., in the z-direction) and are separated by dielectric material 134. For example, vertical plate line structures 438 include plate lines 435 separated by dielectric material 434 analogous to bit lines 148 and dielectric material 134 (refer to FIGS. 4D and 4F). Memory cells 450 are stacked vertically and arrayed laterally within 3D memory device 400. Dielectric materials 106 may be provided at the perimeter of 3D memory device 100.

3D memory device 400 provides a 3D array of memory cells 450 over substrate 102 such that individual ones of memory cells 450 each include transistor 460 such that transistor 460 includes channel structure 108 orthogonal to a word line 116 (i.e., with channel structure 108 extending in the y-direction and word line 116 extending in the x-direction) and a ferroelectric gate dielectric layer 414 between channel structure 108 and word line 116 such that channel structure 108 and word line 116 are substantially parallel to the lateral surface (i.e., they are parallel to the x-y plane). Each of memory cells 450 may also include at least a portion of one of plate lines 435. Plate lines 435 may also be characterized as source lines. Plate lines 435 may include any conductive material or materials such as metals or metal alloys such as copper, cobalt, tungsten, titanium, aluminum, ruthenium, or alloys of such materials. In some embodiments, plate lines 435 and bit lines 148 are the same materials.

Ferroelectric gate dielectric layer 414 provides storage capacity for memory cells 450 due to the nature of the ferroelectric thereof to hold a polarization (i.e., residual charge), as discussed with respect to charge versus voltage graph 198. For example, ferroelectric gate dielectric layer 414 may be programmed by providing a voltage differential across word line 116 and plate line 435. Ferroelectric gate dielectric layer 414 may include any suitable ferroelectric material. In some embodiments, ferroelectric gate dielectric layer 414 includes lead, zirconium, titanium, and oxygen (e.g., lead zirconium titanate, Pb[ZrₓTi₁₋ₓ]O₃). In some embodiments, ferroelectric gate dielectric layer 414 includes barium, titanium, and oxygen (e.g., barium titanate, BaTiO₃). In some embodiments, ferroelectric gate dielectric layer 414 includes lead, titanium, and oxygen (e.g., lead titanate, PbTiO₃). In some embodiments, ferroelectric gate dielectric layer 414 includes barium, strontium, titanium, and oxygen (e.g., barium strontium titanate, BaSrTiO₃). Other ferroelectric materials may be employed.

3D memory device 400 provides a one storage device-one transistor architecture analogous to a 1C-1T architecture. Each memory cell includes a storage device (e.g., ferroelectric gate dielectric layer 414) as provided by part of transistor 460 and transistor 460 itself. The gate of transistor 460 is controlled via word line 116 and the source/drain are coupled to plate line 435 and bit line 148. Each word line 116 and each bit line 148 is coupled to an array of transistors (via gate and source/drain, respectively) to provide access to each memory cell.

As shown, in some embodiments, 3D memory device 400 includes a number of first memory cells 482 each accessed by one of bit lines 148 such that the memory cells are stacked vertically over the lateral surface of substrate 102. Plate line 435 extends vertically along the vertically stacked transistors of first memory cells 482. 3D memory device 400 also includes a number of second memory cells 484 (i.e., in the negative x-direction from first memory cells 482) each accessed by a second of bit lines 148 that are also stacked vertically over the lateral surface. Second memory cells 484 are laterally adjacent first memory cells 482 (i.e., in the negative x-direction). Transistors of second memory cells 484 also contact a different plate line 435 with respect to first memory cells 482 with plate lines 435 being separated in the x-direction by dielectric material 434. Dielectric material 434 may include any suitable insulator or isolation material such as carbon-doped oxide, silicon nitride, silicon oxide, or other carbides or nitrides (e.g., silicon carbide, silicon nitride doped with carbon, or silicon oxynitride). Notably, laterally aligned transistors of first memory cells 482 and second memory cells 484 are coupled to different surface portions at the same vertical height of plate lines 435 and bit lines 148. In addition, 3D memory device 400 includes a number of third memory cells 486 (i.e., in the negative y-direction from first memory cells 482) each accessed by another bit lines 148 that are also stacked vertically over the lateral surface of substrate 102. Third memory cells 486 are laterally opposite one of plate lines 435 from first memory cells 482.

With reference to FIG. 4C, as shown in the across word lines view, word lines 116 extend in the x-direction to control multiple transistors 460 (i.e., arrayed along the x-direction) and the ferroelectric gate dielectric layer thereof such that different regions of word lines 116 are separated from a channel structure 108 of each of transistors 460 by one of ferroelectric gate dielectric layers 414. Such word lines 116, ferroelectric gate dielectric layer 414, and channel structures 108 are isolated and separated from one another by dielectric material 104 and/or dielectric material 130.

As shown in FIG. 4D, illustrating a view across vertical plate line structures 438, plate lines 435 are separated laterally in the x-direction by dielectric material 434. For example, the view across bit lines 148 may be substantially the same with bit lines 148 being separated by dielectric material 134. Such plate lines 435 and bit lines 148 provide access to a stack of transistors that may be individually selected by one of word lines 116, for example.

Turning now to FIG. 4E, a view across isolation between transistor stacks is illustrated. As shown, for transistor stacks that are adjacent one another in the y-direction, dielectric material 134 provides isolation between bit lines 148 (refer to FIG. 4A) and dielectric material 434 provides isolation between plate lines 435. Also as shown, isolation between channel structures 108 is provided in the same x-direction by providing dielectric material 130 between adjacent ones of channel structures 108 of transistors 160. Word lines 116 extend through the x-direction and are evident in the view of FIG. 4E. Similarly, spacers 122 and gate dielectric layers 114 extend in the x-direction. The top down view of FIG. 4F shows the alternating bit lines 148 separated by dielectric materials 134 as well as alternating plate lines 435 and dielectric materials 434 separating them. For example, contact may be made via interconnects or wiring to each of bit lines 148, each of plate lines 435, as well as each of word lines 116 (not shown) to provide read and write access to 3D memory device 400.

3D memory device 400 provides vertical plate line structures 438 having plate lines 435 substantially parallel to bit lines 148 to provide access to memory cells 450. Alternatively, memory cells 450 may be accessed by plate lines that extend substantially parallel to word lines 116 as shown with respect to FIGS. 4A-4F.

FIG. 5A provides an isometric view of an exemplary 3D memory device 500, arranged in accordance with at least some implementations of the present disclosure. FIG. 5B illustrates a view taken along plane B-B (i.e., across the transistor of each memory cell), FIG. 5C illustrates a view taken along plane C-C (i.e., across word lines), FIG. 5D illustrates a view taken along plane D-D (i.e., across plate line structures), FIG. 5E illustrates a view taken along plane E-E (i.e., across isolation between transistor stacks), and FIG. 5F illustrates a view taken along plane F-F (i.e., a top down view).

In 3D memory device 500, a capacitor structure is again replaced by horizontal plate line structures 538, which are detailed in FIGS. 5B-4F, which again provides greater density and other advantages. 3D memory device 500 includes substrate 102 having a lateral surface along the x-y plane. As shown in FIG. 5B, each of memory cells 550 includes transistor 460 (or transistor portion) and corresponding memory structure 470 as provided by the ferroelectric material of ferroelectric gate dielectric 414 of transistor 460 such that the functionality of memory structure 470 is provided by ferroelectric gate dielectric 414 of transistor 460. Each of memory cells 550 may also include a portion of a plate line 535. Plate lines 535 extend laterally with respect to the lateral surface (i.e., in the x-direction) and are separated from one another vertically by dielectric material 534. For example, horizontal plate line structures 538 include plate lines 535 separated by dielectric material 534. Memory cells 550 are stacked vertically and arrayed laterally within 3D memory device 500.

3D memory device 500 provides a 3D array of memory cells 550 over substrate 102 such that individual ones of memory cells 550 each include transistor 460 with transistor 460 including channel structure 108 orthogonal to a word line 116 (i.e., with channel structure 108 extending in the y-direction and word line 116 extending in the x-direction) and ferroelectric gate dielectric layer 414 between channel structure 108 and word line 116 such that channel structure 108 and word line 116 are substantially parallel to the lateral surface (i.e., they are parallel to the x-y plane). Each of memory cells 550 may also include at least a portion of one of plate lines 535. Plate lines 435 may also be characterized as source lines. Plate lines 535 may include any conductive material or materials such as metals or metal alloys such as copper, cobalt, tungsten, titanium, aluminum, ruthenium, or alloys of such materials.

As discussed with respect to 3D memory device 500, ferroelectric gate dielectric layer 414 as deployed in 3D memory device 500 provides storage capacity for memory cells 550 due to the nature of the ferroelectric thereof to hold a polarization (i.e., residual charge). For example, ferroelectric gate dielectric layer 414 may be programmed in the context of 3D memory device 500 by providing a voltage differential across word line 116 and plate line 535. Ferroelectric gate dielectric layer 414 may include any suitable ferroelectric material such as lead, zirconium, titanium, and oxygen (e.g., lead zirconium titanate, Pb[ZrₓTi₁₋ₓ]O₃), barium, titanium, and oxygen (e.g., barium titanate, BaTiO₃), lead, titanium, and oxygen (e.g., lead titanate, PbTiO₃), barium, strontium, titanium, and oxygen (e.g., barium strontium titanate, BaSrTiO₃), or other ferroelectric material.

3D memory device 500 provides a one storage device-one transistor architecture with ach memory cell includes a storage device (e.g., ferroelectric gate dielectric layer 414) as provided by part of transistor 460 and transistor 460 itself. The gate of transistor 460 is controlled via word line 116 and the source/drain are coupled to plate line 535 and bit line 148. Each word line 116 and each bit line 148 is coupled to an array of transistors (via gate and source/drain, respectively) to provide access to each memory cell.

As shown, in some embodiments, 3D memory device 400 includes a number of first memory cells 582 each accessed by one of bit lines 148 such that the memory cells are stacked vertically over the lateral surface of substrate 102. Plate lines 535 extends laterally across the vertically stacked transistors of first memory cells 582 such that each of the vertically stacked transistors is contacted by a different one of the corresponding plate lines 535. 3D memory device 100 also includes a number of second memory cells 584 (i.e., in the negative x-direction from first memory cells 482) each accessed by a second of bit lines 148 that are also stacked vertically over the lateral surface. Second memory cells 584 are laterally adjacent first memory cells 582 (i.e., in the negative x-direction). Transistors of second memory cells 584 are also contacted, separately, by the same plate lines that contact transistors of first memory cells 582. That is, laterally aligned transistors of first and second memory cells 582, 584 (i.e., transistors at the same vertical height) are contacted by the same one of plate lines 535.

Plate lines 535 are vertically separated by dielectric material 534. Dielectric material 434 may include any suitable insulator or isolation material such as carbon-doped oxide, silicon nitride, silicon oxide, or other carbides or nitrides (e.g., silicon carbide, silicon nitride doped with carbon, or silicon oxynitride). In addition, 3D memory device 500 includes a number of third memory cells 586 (i.e., in the negative y-direction from first memory cells 482) each accessed by another bit lines 148 that are also stacked vertically over the lateral surface of substrate 102. Third memory cells 486 are laterally opposite the vertically stacked plate lines 535 from first memory cells 482.

As shown in FIG. 5C, in an across word lines view, word lines 116 extend in the x-direction to control multiple transistors 460 (i.e., arrayed along the x-direction) and the ferroelectric gate dielectric layer thereof. Regions of word lines 116 are separated from a channel structure 108 of each of transistors 460 by one of ferroelectric gate dielectric layers 414 with word lines 116, ferroelectric gate dielectric layer 414, and channel structures 108 being isolated and separated from one another by dielectric material 104 and/or dielectric material 130. In FIG. 4D, which illustrates a view across horizontal plate line structures 538, plate lines 535 are separated vertically (i.e., in the z-direction) by dielectric material 534 and both extend in the x-direction.

In FIG. 5E, a view across isolation between transistor stacks is illustrated. As shown, for transistor stacks that are adjacent one another in the y-direction, dielectric material 134 provides isolation between bit lines 148 (refer to FIG. 5A) and dielectric material 534 provides isolation between plate lines 535, which extend in the x-direction. Also as shown, isolation between channel structures 108 is provided in the same x-direction by providing dielectric material 130 between adjacent ones of channel structures 108 of transistors 460. Word lines 116 extend through the x-direction and are evident in the view of FIG. 4E. Similarly, spacers 122 and gate ferroelectric gate dielectric 414 extend in the x-direction. The top down view of FIG. 5F shows the alternating bit lines 148 separated by dielectric materials 134. In the illustrated view, plate lines 535 are obscured but may be contacted through dielectric material 130. For example, contact may be made via interconnects or wiring to each of bit lines 148, each of plate lines 535 (not shown), and each of word lines 116 (not shown) to provide read and write access to 3D memory device 500.

3D memory devices 100, 200, 300, 400 500 may be fabricated using any suitable technique or techniques. For example, 3D memory devices 100, 200, 300, 400 500 may be formed by providing a layer stack of dielectric materials, forming bit line trenches, performing a cavity etch, forming a conformal channel structure, removing unwanted portions of the channel structure, forming a conformal gate dielectric, removing unwanted portions of the gate dielectric, performing a word line fill, removing unwanted portions of word line fill to form the word lines, etching back for spacers, performing spacer fill, removing unwanted portions of spacer fill to form the spacers, selectively segmenting the transistors, providing a fill in the transistor components, forming the ferroelectric capacitor structure or plate line structure between adjacent transistor rows, trenching for the bit lines, and forming the bit lines. Other techniques may be deployed. Notably, for select ones of 3D memory devices 100, 200, 300, 400 500 such processing may include selectively segmenting or separating ferroelectric capacitor structures or separating the plate line structures to achieve the 3D memory devices discussed herein.

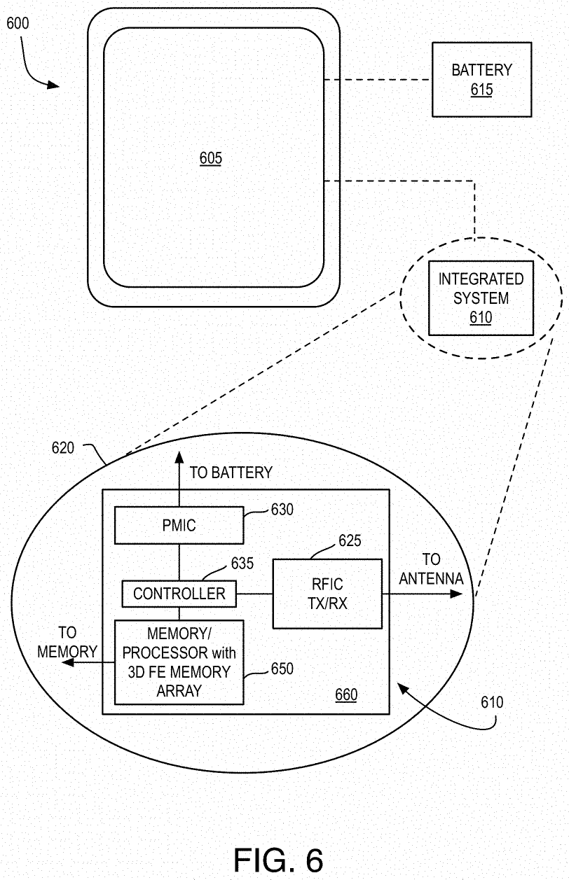

FIG. 6 is an illustrative diagram of a mobile computing platform 600 employing a device having a 3D ferroelectric memory cell architecture, arranged in accordance with at least some implementations of the present disclosure. Any die or device having a structure inclusive of any components, materials, or characteristics discussed herein may be implemented by any component of mobile computing platform 600. For example, one or more of 3D memory devices 200, 300, 400, 500 may be deployed by any component of mobile computing platform 600. Mobile computing platform 600 may be any portable device configured for each of electronic data display, electronic data processing, wireless electronic data transmission, or the like. For example, mobile computing platform 600 may be any of a tablet, a smart phone, a netbook, a laptop computer, etc. and may include a display screen 605, which in the exemplary embodiment is a touchscreen (e.g., capacitive, inductive, resistive, etc. touchscreen), a chip-level (system on chip—SoC) or package-level integrated system 610, and a battery 615. Battery 615 may include any suitable device for providing electrical power such as a device consisting of one or more electrochemical cells and electrodes to couple to an outside device. Mobile computing platform 600 may further include a power supply to convert a source power from a source voltage to one or more voltages employed by other devices of mobile computing platform 600.

Integrated system 610 is further illustrated in the expanded view 620. In the exemplary embodiment, packaged device 650 (labeled “Memory/Processor” in FIG. 6) includes at least one memory chip (e.g., RAM), and/or at least one processor chip (e.g., a microprocessor, a multi-core microprocessor, or graphics processor, or the like). In an embodiment, the package device 650 is a microprocessor including an SRAM cache memory. As shown, device 650 may employ a die or device having any transistor structures and/or related characteristics discussed herein. Packaged device 650 may be further coupled to (e.g., communicatively coupled to) a board, a substrate, or an interposer 660 along with, one or more of a power management integrated circuit (PMIC) 630, RF (wireless) integrated circuit (RFIC) 625 including a wideband RF (wireless) transmitter and/or receiver (TX/RX) (e.g., including a digital baseband and an analog front end module further comprises a power amplifier on a transmit path and a low noise amplifier on a receive path), and a controller 635 thereof. In general, packaged device 650 may be also be coupled to (e.g., communicatively coupled to) display screen 605. As shown, one or both of PMIC 630 and/or RFIC 625 may employ a die or device having any transistor structures and/or related characteristics discussed herein.

Functionally, PMIC 630 may perform battery power regulation, DC-to-DC conversion, etc., and so has an input coupled to battery 615 and with an output providing a current supply to other functional modules. In an embodiment, PMIC 630 may perform high voltage operations. As further illustrated, in the exemplary embodiment, RFIC 625 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. In alternative implementations, each of these board-level modules may be integrated onto separate ICs coupled to the package substrate of packaged device 650 or within a single IC (SoC) coupled to the package substrate of the packaged device 650.

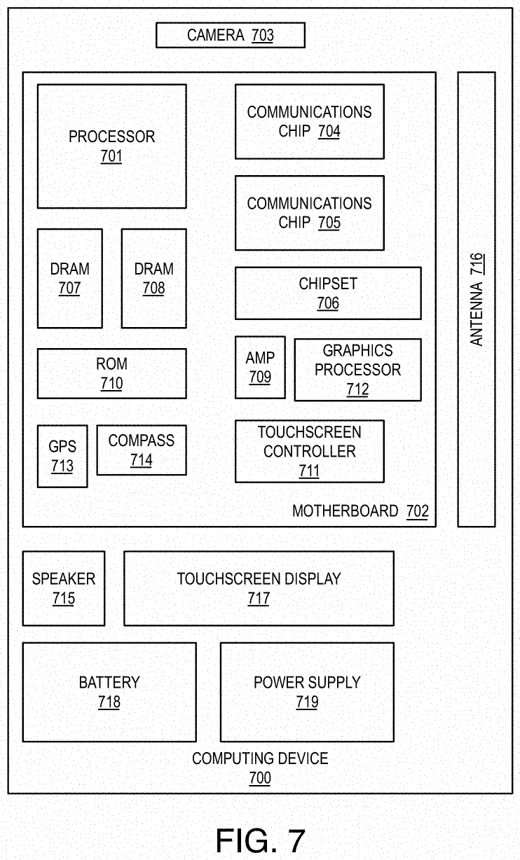

FIG. 7 is a functional block diagram of a computing device 700, arranged in accordance with at least some implementations of the present disclosure. Computing device 700 may be found inside platform 600, for example, and further includes a motherboard 702 hosting a number of components, such as but not limited to a processor 701 (e.g., an applications processor) and one or more communications chips 704, 705. Processor 701 may be physically and/or electrically coupled to motherboard 702. In some examples, processor 701 includes an integrated circuit die packaged within the processor 701. In general, the term “processor” may refer to any device or portion of a device that processes electronic data from registers and/or memory to transform that electronic data into other electronic data that may be stored in registers and/or memory. Any one or more device or component of computing device 700 may include a die or device having a 3D ferroelectric memory cell architecture and/or related characteristics discussed herein.

In various examples, one or more communication chips 704, 705 may also be physically and/or electrically coupled to the motherboard 702. In further implementations, communication chips 704 may be part of processor 701. Depending on its applications, computing device 700 may include other components that may or may not be physically and electrically coupled to motherboard 702. These other components may include, but are not limited to, volatile memory (e.g., DRAM) 707, 708, non-volatile memory (e.g., ROM) 710, a graphics processor 712, flash memory, global positioning system (GPS) device 713, compass 714, a chipset 706, an antenna 716, a power amplifier 709, a touchscreen controller 711, a touchscreen display 717, a speaker 715, a camera 703, a battery 718, and a power supply 719, as illustrated, and other components such as a digital signal processor, a crypto processor, an audio codec, a video codec, an accelerometer, a gyroscope, and a mass storage device (such as hard disk drive, solid state drive (SSD), compact disk (CD), digital versatile disk (DVD), and so forth), or the like.

Communication chips 704, 705 may enable wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 704, 705 may implement any of a number of wireless standards or protocols, including but not limited to those described elsewhere herein. As discussed, computing device 700 may include a plurality of communication chips 704, 705. For example, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others. Furthermore, power supply 719 may convert a source power from a source voltage to one or more voltages employed by other devices of computing device 700 (or mobile computing platform 600). In some embodiments, power supply 719 converts an AC power to DC power. In some embodiments, power supply 719 converts an DC power to DC power at one or more different (lower) voltages. In some embodiments, multiple power supplies are staged to convert from AC to DC and then from DC at a higher voltage to DC at a lower voltage as specified by components of computing device 700.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

The following embodiments pertain to further embodiments.

In one or more first embodiments, a memory device comprises a three-dimensional (3D) array of memory cells over a substrate, the substrate comprising a lateral surface, individual ones of the memory cells of the 3D array comprising a transistor comprising a channel structure adjacent and orthogonal to a word line, the channel structure and the word line substantially parallel to the lateral surface and at least a portion of a capacitor structure, the capacitor structure comprising a ferroelectric layer between first and second metal plates, wherein the channel structure extends between and contacts a bit line and the first metal plate, wherein the bit line is substantially orthogonal to the lateral surface.

In one or more second embodiments, further to the first embodiment, a plurality of first memory cells each accessed by the bit line are stacked vertically over the lateral surface and the capacitor structure comprises a plurality of regions extending laterally from a trunk region of the capacitor structure, each of the plurality of regions adjacent to a corresponding transistor of individual ones of the plurality of first memory cells.

In one or more third embodiments, further to the first or second embodiments, a plurality of second memory cells each accessed by a second bit line are stacked vertically over the lateral surface and laterally adjacent the plurality of first memory cells, wherein the regions of the capacitor structure are adjacent a corresponding transistor of individual ones of the plurality of second memory cells, and wherein the first and second bit lines are separated by dielectric material.

In one or more fourth embodiments, further to any of the first through third embodiments, a plurality of second memory cells each accessed by a second bit line are stacked vertically over the lateral surface and laterally opposite the capacitor structure from the plurality of first memory cells, wherein second regions of the capacitor structure extending from the trunk structure are adjacent a corresponding transistor of individual ones of the plurality of second memory cells, individual ones of the regions and second regions extending from the trunk structure substantially parallel to the lateral surface.

In one or more fifth embodiments, further to any of the first through fourth embodiments, a plurality of second memory cells each accessed by a second bit line are stacked vertically over the lateral surface and laterally adjacent the plurality of first memory cells, individual ones of the second memory cells comprising a second transistor and at least a portion of a second capacitor structure, the second capacitor structure separated from the capacitor structure by first dielectric material and the first and second bit lines separated by the first dielectric material or a second dielectric material.

In one or more sixth embodiments, further to any of the first through fifth embodiments, individual ones of the second transistors comprise a second channel structure adjacent corresponding ones of the word lines, the second channel structure extending from the second bit line to the second capacitor structure.

In one or more seventh embodiments, further to any of the first through sixth embodiments, a plurality of first memory cells each accessed by the bit line are stacked vertically over the lateral surface, each of the plurality of first memory cells comprising a first transistor and a first capacitor structure, wherein adjacent ones of the first capacitor structures are separated by dielectric material.

In one or more eighth embodiments, further to any of the first through seventh embodiments, a plurality of second memory cells each accessed by a second bit line are stacked vertically over the lateral surface and laterally adjacent the plurality of first memory cells, individual ones of the second memory cells comprising a second transistor and a portion of one of the first capacitor structures.

In one or more ninth embodiments, further to any of the first through eighth embodiments, the ferroelectric layer comprises one of lead, zirconium, titanium, and oxygen or barium, strontium, titanium, and oxygen.

In one or more tenth embodiments, a memory device comprises a three-dimensional (3D) array of memory cells over a substrate, the substrate comprising a lateral surface, individual ones of the memory cells of the 3D array comprising a transistor comprising a channel structure orthogonal to a word line and a ferroelectric gate dielectric layer between the channel structure and the word line, the channel structure and the word line substantially parallel to the lateral surface and at least a portion of a metal plate line, the metal plate line substantially orthogonal to the lateral surface, wherein the channel structure extends between and contacts a bit line and the portion of the metal plate line, wherein the bit line is substantially orthogonal to the lateral surface.

In one or more eleventh embodiments, further to the tenth embodiment, a plurality of first memory cells each accessed by the bit line are stacked vertically over the lateral surface and the first memory cells each comprises a transistor comprising a channel structure that extends between and contacts the bit line and the metal plate line.

In one or more twelfth embodiments, further to the tenth or eleventh embodiments, a plurality of second memory cells each accessed by a second bit line are stacked vertically over the lateral surface and laterally adjacent the plurality of first memory cells, wherein second portions of the metal plate line are adjacent a corresponding transistor of individual ones of the plurality of second memory cells, and wherein the first and second bit lines are separated by dielectric material.

In one or more thirteenth embodiments, further to any of the tenth through tenth embodiments, a plurality of second memory cells each accessed by a second bit line are stacked vertically over the lateral surface and laterally opposite the metal plate line from the plurality of first memory cells, wherein second regions of the metal plate line are adjacent a corresponding transistor of individual ones of the plurality of second memory cells.

In one or more fourteenth embodiments, further to any of the tenth through tenth embodiments, the ferroelectric gate dielectric layer and the channel structure of the individual ones of the transistors are over a top, bottom, and side surface of the word line.

In one or more fifteenth embodiments, further to any of the tenth through fourteenth embodiments, the ferroelectric gate dielectric layer comprises one of lead, zirconium, titanium, and oxygen or barium, strontium, titanium, and oxygen.

In one or more sixteenth embodiments, a memory device comprises a three-dimensional (3D) array of memory cells over a substrate, the substrate comprising a lateral surface, individual ones of the memory cells of the 3D array comprising a transistor comprising a channel structure orthogonal to a word line and a ferroelectric gate dielectric layer between the channel structure and the word line, the channel structure and the word line substantially parallel to the lateral surface and at least a portion of a metal plate line, the metal plate line substantially parallel to the word line, wherein the channel structure extends between and contacts a bit line and the portion of the metal plate line, wherein the bit line is substantially orthogonal to the lateral surface.

In one or more seventeenth embodiments, further to the sixteenth embodiment, a plurality of first memory cells each accessed by the bit line are stacked vertically over the lateral surface and the first memory cells each comprises a transistor comprising a channel structure that extends between and contacts a first portion of a separate metal plate line, the metal plate lines separated by dielectric material.

In one or more eighteenth embodiments, further to the sixteenth or seventeenth embodiments, a plurality of second memory cells each accessed by a second bit line are stacked vertically over the lateral surface and laterally adjacent the plurality of first memory cells, wherein second portions of the metal plate lines are adjacent a corresponding transistor of individual ones of the plurality of second memory cells, and wherein the first and second bit lines are separated by dielectric material.

In one or more nineteenth embodiments, further to any of the sixteenth through eighteenth embodiments, a plurality of second memory cells each accessed by a second bit line are stacked vertically over the lateral surface and laterally opposite the metal plate lines from the plurality of first memory cells, wherein second regions of the metal plate lines are adjacent a corresponding transistor of individual ones of the plurality of second memory cells.

In one or more twentieth embodiments, further to any of the sixteenth through nineteenth embodiments, the ferroelectric gate dielectric layer and the channel structure of the individual ones of the transistors are over a top, bottom, and side surface of the word line.

In one or more twenty-first embodiments, further to any of the sixteenth through twentieth embodiments, the ferroelectric gate dielectric layer comprises one of lead, zirconium, titanium, and oxygen or barium, strontium, titanium, and oxygen.

In one or more twenty-second embodiments, a system comprises a power supply and an integrated circuit die coupled to the power supply, the integrated circuit die comprising a memory device according to any of the first through twenty-first embodiments.

It will be recognized that the invention is not limited to the embodiments so described, but can be practiced with modification and alteration without departing from the scope of the appended claims. For example, the above embodiments may include specific combination of features. However, the above embodiments are not limited in this regard and, in various implementations, the above embodiments may include the undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. A memory device, comprising:
a three-dimensional (3D) array of memory cells over a substrate, the substrate comprising a lateral surface, individual ones of the memory cells of the 3D array comprising:
a transistor comprising a channel structure adjacent and orthogonal to a word line, the channel structure and the word line substantially parallel to the lateral surface; and
at least a portion of a capacitor structure, the capacitor structure comprising a ferroelectric layer between first and second metal plates, wherein the channel structure extends between and contacts a bit line and the first metal plate, wherein the bit line is substantially orthogonal to the lateral surface.

2. The memory device of claim 1, wherein a plurality of first memory cells each accessed by the bit line are stacked vertically over the lateral surface and the capacitor structure comprises a plurality of regions extending laterally from a trunk region of the capacitor structure, each of the plurality of regions adjacent to a corresponding transistor of individual ones of the plurality of first memory cells.

3. The memory device of claim 2, wherein a plurality of second memory cells each accessed by a second bit line are stacked vertically over the lateral surface and laterally adjacent the plurality of first memory cells, wherein the regions of the capacitor structure are adjacent a corresponding transistor of individual ones of the plurality of second memory cells, and wherein the first and second bit lines are separated by dielectric material.

4. The memory device of claim 2, wherein a plurality of second memory cells each accessed by a second bit line are stacked vertically over the lateral surface and laterally opposite the capacitor structure from the plurality of first memory cells, wherein second regions of the capacitor structure extending from the trunk structure are adjacent a corresponding transistor of individual ones of the plurality of second memory cells, individual ones of the regions and second regions extending from the trunk structure substantially parallel to the lateral surface.

5. The memory device of claim 2, wherein a plurality of second memory cells each accessed by a second bit line are stacked vertically over the lateral surface and laterally adjacent the plurality of first memory cells, individual ones of the second memory cells comprising:
a second transistor; and
at least a portion of a second capacitor structure, the second capacitor structure separated from the capacitor structure by first dielectric material and the first and second bit lines separated by the first dielectric material or a second dielectric material.

6. The memory device of claim 5, wherein individual ones of the second transistors comprise a second channel structure adjacent corresponding ones of the word lines, the second channel structure extending from the second bit line to the second capacitor structure.

7. The memory device of claim 1, wherein a plurality of first memory cells each accessed by the bit line are stacked vertically over the lateral surface, each of the plurality of first memory cells comprising a first transistor and a first capacitor structure, wherein adjacent ones of the first capacitor structures are separated by dielectric material.

8. The memory device of claim 7, wherein a plurality of second memory cells each accessed by a second bit line are stacked vertically over the lateral surface and laterally adjacent the plurality of first memory cells, individual ones of the second memory cells comprising:
a second transistor; and
a portion of one of the first capacitor structures.

9. The memory device of claim 1, wherein the ferroelectric layer comprises one of lead, zirconium, titanium, and oxygen or barium, strontium, titanium, and oxygen.

10. A memory device, comprising:
a three-dimensional (3D) array of memory cells over a substrate, the substrate comprising a lateral surface, individual ones of the memory cells of the 3D array comprising:
a transistor comprising a channel structure orthogonal to a word line and a ferroelectric gate dielectric layer between the channel structure and the word line, the channel structure and the word line substantially parallel to the lateral surface; and
at least a portion of a metal plate line, the metal plate line substantially orthogonal to the lateral surface, wherein the channel structure extends between and contacts a bit line and the portion of the metal plate line, wherein the bit line is substantially orthogonal to the lateral surface.

11. The memory device of claim 10, wherein a plurality of first memory cells each accessed by the bit line are stacked vertically over the lateral surface and the first memory cells each comprises a transistor comprising a channel structure that extends between and contacts the bit line and the metal plate line.

12. The memory device of claim 11, wherein a plurality of second memory cells each accessed by a second bit line are stacked vertically over the lateral surface and laterally adjacent the plurality of first memory cells, wherein second portions of the metal plate line are adjacent a corresponding transistor of individual ones of the plurality of second memory cells, and wherein the first and second bit lines are separated by dielectric material.

13. The memory device of claim 11, wherein a plurality of second memory cells each accessed by a second bit line are stacked vertically over the lateral surface and laterally opposite the metal plate line from the plurality of first memory cells, wherein second regions of the metal plate line are adjacent a corresponding transistor of individual ones of the plurality of second memory cells.

14. The memory device of claim 10, wherein the ferroelectric gate dielectric layer and the channel structure of the individual ones of the transistors are over a top, bottom, and side surface of the word line.

15. The memory device of claim 10, wherein the ferroelectric gate dielectric layer comprises one of lead, zirconium, titanium, and oxygen or barium, strontium, titanium, and oxygen.

16. A memory device, comprising:
a three-dimensional (3D) array of memory cells over a substrate, the substrate comprising a lateral surface, individual ones of the memory cells of the 3D array comprising:
a transistor comprising a channel structure orthogonal to a word line and a ferroelectric gate dielectric layer between the channel structure and the word line, the channel structure and the word line substantially parallel to the lateral surface; and
at least a portion of a metal plate line, the metal plate line substantially parallel to the word line, wherein the channel structure extends between and contacts a bit line and the portion of the metal plate line, wherein the bit line is substantially orthogonal to the lateral surface.

17. The memory device of claim 16, wherein a plurality of first memory cells each accessed by the bit line are stacked vertically over the lateral surface and the first memory cells each comprises a transistor comprising a channel structure that extends between and contacts a first portion of a separate metal plate line, the metal plate lines separated by dielectric material.

18. The memory device of claim 17, wherein a plurality of second memory cells each accessed by a second bit line are stacked vertically over the lateral surface and laterally adjacent the plurality of first memory cells, wherein second portions of the metal plate lines are adjacent a corresponding transistor of individual ones of the plurality of second memory cells, and wherein the first and second bit lines are separated by dielectric material.

19. The memory device of claim 17, wherein a plurality of second memory cells each accessed by a second bit line are stacked vertically over the lateral surface and laterally opposite the metal plate lines from the plurality of first memory cells, wherein second regions of the metal plate lines are adjacent a corresponding transistor of individual ones of the plurality of second memory cells.

20. The memory device of claim 16, wherein the ferroelectric gate dielectric layer and the channel structure of the individual ones of the transistors are over a top, bottom, and side surface of the word line.

21. The memory device of claim 16, wherein the ferroelectric gate dielectric layer comprises one of lead, zirconium, titanium, and oxygen or barium, strontium, titanium, and oxygen.
